(19) United States
(12) Patent Application Publication
(10) Pub. No.: US 2024/0167939 A1
(43) Pub. Date: May 23, 2024

(54) SYSTEMS AND METHODS FOR HEAT EXCHANGE

(71) Applicant: 10x Genomics, Inc., Pleasanton, CA (US)

(72) Inventors: Evan DeJARNETTE, San Francisco, CA (US); Tyler DRAKE, Livermore, CA (US); Hendricus MARINDRA, Livermore, CA (US); Jack HERRERA, Foster City, CA (US); Eric EVJE, Oakland, CA (US); Alexander Post KINDWALL, Pleasanton, CA (US); David MORGAN, Castro Valley, CA (US)

(73) Assignee: 10x Genomics, Inc., Pleasanton, CA (US)

(21) Appl. No.: 18/507,648

(22) Filed: Nov. 13, 2023

Related U.S. Application Data
(60) Provisional application No. 63/426,142, filed on Nov. 17, 2022.

(51) Int. Cl. G01N 21/03; G01N 21/75; H05K 7/20

(52) U.S. Cl. CPC G01N 21/0332; G01N 21/75; H05K 7/20281

(57) ABSTRACT

Various embodiments of the present disclosure disclose methods and systems for heat exchange in an opto-fluidic instrument. The opto-fluidic instrument includes a sample interface module (SIM), an illumination module, a camera module, and a reagent deck. A coolant from a coolant reservoir is directed into one or more of the modules so that heat exchange occurs at each module with the coolant. The heated coolant from the one or more modules flows to a radiator for cooling, for example, with fans flowing ambient air over the radiator, before the cooled coolant is returned to the coolant reservoir for subsequent use in cooling the modules.

### CROSS REFERENCE TO RELATED APPLICATION

This application is a continuation application of International (PCT) application PCT/US23/79480 filed Nov. 13, 2023, which claims priority to U.S. provisional patent application Ser. No. 63/426,142 filed Nov. 17, 2022, the entire contents of which are incorporated herein by reference and relied upon.

### FIELDS OF THE DISCLOSURE

The present disclosure is directed to systems and methods for heat exchange in an opto-fluidic instrument. In particular, the present disclosure describes methods and systems for circulating a working fluid (e.g., a coolant) to various modules of the opto-fluidic instrument having integrated optics and fluidics modules to allow for heat exchange between the modules and the working fluid.

### SUMMARY

Various embodiments of the present disclosure disclose a heat transfer system comprising a reservoir, a radiator, and a pump. In various embodiments, the reservoir is configured to store a liquid coolant. Further, the pump is configured to pump the liquid coolant from the reservoir to the radiator via a plurality of modules of an opto-fluidic instrument. In various instances, the plurality of modules of the opto-fluidic instrument include a sample interface module (SIM), an illumination module, a camera module, and a reagent deck. The SIM is configured to support a sample and includes a SIM cooling block that is thermally coupled to the sample. The illumination module includes a light emitting diode (LED) cooling block and one or more LEDs that are configured to illuminate the sample. The camera module is configured to image the sample and includes a camera cooling block. The reagent deck is configured to store reagents for treating the sample during a plurality of imaging cycles. Further, the reagent deck includes a reagent deck cooling block that is thermally coupled to the reagents.

Various embodiments of the present disclosure disclose a system for controlling temperature of an opto-fluidic instrument. The system for controlling the temperature of the opto-fluidic instrument comprise a reservoir, a radiator, one or more first fluid paths, a pump, a sensor, and a controller. The reservoir is configured to store a liquid coolant. The one or more first fluid paths are configured to connect the reservoir to a plurality of modules of the opto-fluidic instrument. In some instances, the plurality of modules can include the afore-mentioned SIM, illumination module, camera module, and reagent deck. The pump is configured to pump the liquid coolant from the reservoir to at least one of the plurality of modules via the one or more first fluid paths. The sensor is disposed along the one or more first fluid paths or is operationally connected to the one or more of the plurality of modules and is configured to perform a measurement of the one or more first fluid paths or the one or more of the plurality of modules, respectively. The controller is communicatively coupled to the sensor and the pump, and is configured to adjust a flow rate of the pump in response to receiving the measurement from the sensor.

Various embodiments of the present disclosure disclose a method for controlling the temperature of an opto-fluidic instrument. In various embodiments, the method comprises pumping, using a pump of an opto-fluidic instrument, a coolant from a coolant source to cool each one of a plurality of modules of an opto-fluidic instrument. In some instances, the plurality of modules can include the afore-mentioned SIM, illumination module, camera module, and reagent deck. The method further comprises receiving, at a radiator of the opto-fluidic instrument, the coolant after the coolant traverses each one of a plurality of modules. Further, the method comprises cooling, using a cooling fan of the opto-fluidic instrument, the received coolant.

### BRIEF DESCRIPTION OF THE DRAWINGS

For a more complete understanding of the principles disclosed herein, and the advantages thereof, reference is now made to the following descriptions taken in conjunction with the accompanying drawings, in which:

FIG. 1 is an example workflow of analysis of a biological sample (e.g., various cell, tissue, fluid, etc. sample and/or swab) using an opto-fluidic instrument, according to various embodiments.

FIG. 2 is a schematic of a heat exchange system for controlling the temperature of modules of an opto-fluidic instrument, according to various embodiments.

FIG. 3 is a schematic of series and parallel fluidic connections between a coolant reservoir, a radiator, and modules of an opto-fluidic instrument, according to various embodiments.

FIG. 4 shows an example illustration of a splitting manifold that fluidically connects the modules of an opto-fluidic instrument in parallel, according to various embodiments.

FIGS. 5A-5C show example illustrations of a cooling block including a heat sink with a fluid path therein for flowing coolants, according to various embodiments.

FIGS. 6A-6C show example illustrations of a cooling block including a heat sink with fins for flowing coolants therebetween, according to various embodiments.

FIG. 7 is a plot illustrating cooling performance of the disclosed heat exchange system in controlling the temperature of reagents in an opto-fluidic instrument, according to various embodiments.

FIG. 8 is a plot illustrating temperatures of a reagent deck cooling block of an opto-fluidic instrument during an operation of a heat exchange system, according to various embodiments.

FIG. 9 is a flowchart illustrating a method for controlling the temperature of modules of an opto-fluidic instrument, according to various embodiments.

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

### I. Overview

Target molecules (e.g., nucleic acids, proteins, antibodies, etc.) can be detected in biological samples (e.g., one or more cells or a tissue sample) using an instrument having integrated optics and fluidics modules (an “opto-fluidic instrument” or “opto-fluidic system”). In an opto-fluidic instrument, the fluidics module is configured to deliver one or more reagents (e.g., fluorescent probes) to the biological sample and/or remove spent reagents therefrom. Additionally, the optics module is configured to illuminate the biological sample with light having one or more spectral emission curves (over a range of wavelengths) and subsequently capture one or more images of emitted light signals from the biological sample during one or more probing cycles. In various embodiments, the captured images may be processed in real time and/or at a later time to determine the presence of the one or more target molecules in the biological sample, as well as three-dimensional position information associated with each detected target molecule. Additionally, the opto-fluidics instrument includes a sample module configured to receive (and, optionally, secure) one or more biological samples. In some instances, the sample module includes an X-Y stage configured to move the biological sample along an X-Y plane (e.g., perpendicular to an objective lens of the optics module).

In various embodiments, the opto-fluidic instrument is configured to analyze one or more target molecules in their naturally occurring place (i.e., in situ) within the biological sample. For example, an opto-fluidic instrument may be an in situ analysis system used to analyze a biological sample and detect target molecules including but not limited to DNA, RNA, proteins, antibodies, and/or the like.

A sample disclosed herein can be or be derived from any biological sample. Biological samples may be obtained from any suitable source using any of a variety of techniques including, but not limited to, biopsy, surgery, and laser capture microscopy (LCM), and generally includes cells, tissues, and/or other biological material from the subject. A biological sample can be obtained from a prokaryote such as a bacterium, an archaea, a virus, or a viroid. A biological sample can also be obtained from eukaryotic mammalian and eukaryotic non-mammalian organisms (e.g., a plant, a fungus an insect, an arachnid, a nematoda, a reptile, or an amphibian). A biological sample from an organism may comprise one or more other organisms or components therefrom. For example, a mammalian tissue section may comprise a prion, a viroid, a virus, a bacterium, a fungus, or components from other organisms, in addition to mammalian cells and non-cellular tissue components. Subjects from which biological samples can be obtained can be healthy or asymptomatic subjects, subjects that have or are suspected of having a disease (e.g., an individual with a disease such as cancer) or a pre-disposition to a disease, and/or subjects in need of therapy or suspected of needing therapy.

The biological sample can include any number of macromolecules, for example, cellular macromolecules and organelles (e.g., mitochondria and nuclei). The biological sample can be obtained as a tissue sample, such as a tissue section, biopsy, a core biopsy, needle aspirate, or fine needle aspirate. The sample can be a fluid sample, such as a blood sample, urine sample, or saliva sample. The sample can be a skin sample, a colon sample, a cheek swab, a vaginal swab, wound swab, nasal swab, a histology sample, a histopathology sample, a plasma or serum sample, a tumor sample, fetal cells, living cells, cultured cells, a clinical sample such as, for example, whole blood or blood-derived products, blood cells, spinal fluid, lymphatic fluid, or cultured tissues or cells, including cell suspensions.

In some embodiments, the biological sample may comprise cells or a tissue sample which are deposited on a substrate. As described herein, a substrate can be any support that is insoluble in aqueous liquid and allows for positioning of biological samples, analytes, features, and/or reagents on the support. In some embodiments, a biological sample is attached to a substrate. In some embodiments, the substrate is optically transparent to facilitate analysis on the opto-fluidic instruments disclosed herein. For example, in some instances, the substrate is a glass substrate (e.g., a microscopy slide, cover slip, or other glass substrate). Attachment of the biological sample can be irreversible or reversible, depending upon the nature of the sample and subsequent steps in the analytical method. In certain embodiments, the sample can be attached to the substrate reversibly by applying a suitable polymer coating to the substrate and contacting the sample to the polymer coating. The sample can then be detached from the substrate, e.g., using an organic solvent that at least partially dissolves the polymer coating. Hydrogels are examples of polymers that are suitable for this purpose. In some embodiments, the substrate can be coated or functionalized with one or more substances to facilitate attachment of the sample to the substrate. Suitable substances that can be used to coat or functionalize the substrate include, but are not limited to, lectins, poly-lysine, antibodies, and polysaccharides.

A variety of steps can be performed to prepare or process a biological sample for and/or during an assay using the opto-fluidic instruments disclosed herein. Except where indicated otherwise, the preparative or processing steps described below can generally be combined in any manner and in any order to appropriately prepare or process a particular sample for and/or analysis.

For example, a biological sample can be harvested from a subject (e.g., via surgical biopsy, whole subject sectioning) and/or grown in vitro on a growth substrate or culture dish as a population of cells and prepared for analysis as a tissue slice or tissue section (e.g., a fresh frozen, fixed frozen, or formalin fixed paraffin embedded (FFPE) tissue section). The thickness of a tissue section typically depends on the method used to prepare the section and the physical characteristics of the tissue, and therefore sections having a wide variety of different thicknesses can be prepared and used.

In some instances, the biological sample is fixed in any of a variety of suitable fixatives to preserve the biological structure of the sample prior to analysis. Exemplary fixatives include formalin, formaldehyde, ethanol, methanol, acetone, paraformaldehyde (PFA)-Triton, and combinations thereof.

In some embodiments, a biological sample can be permeabilized to facilitate transfer of analytes out of the sample, and/or to facilitate transfer of species (such as probes or probes sets) into the sample. In general, a biological sample can be permeabilized by exposing the sample to one or more permeabilizing agents. Suitable agents for this purpose include, but are not limited to, organic solvents (e.g., acetone, ethanol, and methanol), cross-linking agents (e.g., paraformaldehyde), detergents (e.g., saponin, Triton X-100™ or Tween-20™), and enzymes (e.g., trypsin, proteases).

In some embodiments, the biological sample is embedded in a polymer and/or crosslinked matrix (e.g., a hydrogel matrix). Embedding the sample in this manner typically involves contacting the biological sample with a hydrogel such that the biological sample becomes surrounded by the hydrogel. For example, the sample (e.g., a tissue section on a substrate, such as a glass substrate) can be embedded by contacting the sample with a suitable polymer material and activating the polymer material to form a hydrogel. In some embodiments, the hydrogel is formed such that the hydrogel is internalized within the biological sample. In some embodiments, the biological sample (including biological analytes) is immobilized in the hydrogel via cross-linking of the polymer material that forms the hydrogel. Cross-linking can be performed chemically and/or photochemically, or alternatively by any other suitable hydrogel-formation method. In some instances, biological molecules (or derivatives thereof) are cross-linked or otherwise covalently attached to the hydrogel. For example, in some embodiments, nucleic acid molecules (or derivatives thereof, such as an amplification product or probe(s) bound to cellular nucleic acid molecule) in a tissue sample are cross-linked or otherwise covalently attached to the hydrogel.

Hydrogels embedded within biological samples can be cleared using any suitable method. For example, electrophoretic tissue clearing methods or surfactant-based (e.g., sodium dodecyl sulfate (SDS)) clearing methods can be used to remove biological macromolecules from the hydrogel-embedded sample.

Tissue clearing is a process of optically resolving a sample or complex biological material, such as whole organs, large tissue, and cellular models, with minimal changes to morphology and without compromising the ability for immunolabeling or fluorescence imaging detection. In various embodiments, refractive index matching is used for obtaining fluorescence images. Mismatching among mediums can cause loss of imaging resolution, as light may travel through the sample itself, a mounting media, glass coverslip, oil, and/or a microscope objective. In various embodiments, the amount of variable scattering of light from cellular membranes, lipids, and/or molecules of the specimen is reduced (e.g., minimized) using the various methods described herein. Heterogeneity of scattering among the cellular components may lead to an increase in opaqueness of an image. In various embodiments, a denser makeup of lipids, trafficking organelles, and other subcellular molecules may increase lateral, or non-forward, light scattered. In various embodiments, non-forward light scattering in situ may not pass through the specimen, as it is exacerbated by the continuous, pinball like, interactions of scattered light with neighboring molecules. In various embodiments, through the multiplicity of scattering, refraction, and absorbance the energy of light may be reduced or ultimately lost, leading to a distorted and white, non-translucent image. In various embodiments, a clearing reagent and mountant optically clears the sample by matching the refractive index to minimizing the light scattering through the specimen and to the microscope objective.

In various embodiments, optical clearing may be performed via various different approaches, primarily being divided into chemical and matrix-based approaches. In various embodiments, chemical approaches include aqueous-based or solvent-based approaches to achieve a highly resolved 3D image for immunolabeling, immuno-cytochemistry, immuno-histochemistry, and/or immunofluorescence. In various embodiments, aqueous-based clearing approaches are generally used to avoid dehydration and toxicity, which can destroy the integrity of a sample.

In various embodiments, passive clarity technique (PACT) is a passive tissue clearing and immunolabeling protocol. In various embodiments, PACT is used for intact thick organs. In various embodiments, RIMS includes a protocol for passive tissue clearing and immunostaining of intact organs that is compatible for long-term storage and has imaging media that preserves fluorescent markers over months.

In various embodiments, refractive index matching solutions (RIMS) may be produced with sugar or glycerol for simple, passive immersion. This may be used with thinner or smaller samples, because they are easier to clear and can maintain fluorescent protein emission. In various embodiments, such immersion techniques may achieve less than 1.5 refractive index and can take days to achieve clearing, resulting in reduced image quality when compared to solvent approaches, due to refractive index mismatching between the cleared sample, the glass coverslip, and immersion oil (glass and oil have an RI of 1.51). As sugar or glycerol solutions may take extended periods for clearing, a sample can experience considerable shrinkage while losing lipid content. In various embodiments, commercially available solutions control morphological alterations and loss of lipid content while achieving a higher refractive index of 1.52. In various embodiments, considerations for clearing include sample type and thickness so that there is minimal shrinkage of the sample and preservation of lipid content and fluorescence.

In various embodiments, perfusion-assisted agent release in situ (PARS) includes a method for whole-body clearing and phenotyping compatible with endogenous fluorescence. In various embodiments, all steps for PARS, including preservation, clearing, and labeling, are performed in situ prior to tissue extraction. In various embodiments, PARS, together with RIMS, transform opaque, intact, whole-organisms into optically transparent, fluorescently labeled samples for visualization with conventional confocal microscopy and phenotypic analysis at the cellular, subcellular, and/or single-molecule transcripts level as described in Single-Cell Phenotyping within Transparent Intact Tissue through Whole-Body Clearing by Yang et al. Cell. Vol 158, Issue 4, P 945-958, Aug. 14, 2014 (accessible online at https://doi.org/10.1016/j.cell.2014.07.017).

A biological sample may comprise one or a plurality of analytes of interest. The opto-fluidic instruments disclosed herein can be used to detect and analyze a wide variety of different analytes. In some aspects, an analyte can include any biological substance, structure, moiety, or component to be analyzed. For example, the analyte may include any biomolecule or chemical compound, including a macromolecule such as a protein or peptide, a lipid or a nucleic acid molecule, or a small molecule, including organic or inorganic molecules. The analyte may be a cell or a microorganism, including a virus, or a fragment or product thereof. An analyte can be any substance or entity for which a specific binding partner (e.g., an affinity binding partner) can be developed and detected (e.g., using the opto-fluidic instruments disclosed herein).

Analytes of particular interest may include nucleic acid molecules, such as DNA (e.g. genomic DNA, mitochondrial DNA, plastid DNA, viral DNA, etc.) and RNA (e.g. mRNA, microRNA, rRNA, snRNA, viral RNA, etc.), and synthetic and/or modified nucleic acid molecules, (e.g. including nucleic acid domains comprising or consisting of synthetic or modified nucleotides such as LNA, PNA, morpholino, etc.), proteinaceous molecules such as peptides, polypeptides, proteins or prions or any molecule which includes a protein or polypeptide component, etc., or fragments thereof. The analyte may be a single molecule or a complex that contains two or more molecular subunits, e.g., including but not limited to complexes between proteins or peptides and nucleic acid molecules such as DNA or RNA, e.g., interactions between proteins and nucleic acids, e.g., regulatory factors, such as transcription factors, and DNA or RNA.

In some embodiments, the opto-fluidic instruments described herein can be utilized for the in situ detection and analysis of cellular analytes, (such as nucleic acid sequences), such as fluorescent in situ hybridization (FISH)-based methods, in situ transcriptomic analysis, or in situ sequencing, for example from intact tissues or samples in which the spatial information has been preserved. In some aspects, the embodiments can be applied in an imaging or detection method for multiplexed nucleic acid analysis. In some aspects, the provided opto-fluidic instruments can be used to detect a signal associated with a detectable label of a nucleic acid probe that is hybridized to a target sequence of a target nucleic acid in a biological sample.

Disclosed herein, in some aspects, are labelling agents (e.g., nucleic acid probes and/or probe sets) that are introduced into a cell or used to otherwise detect an analyte in a biological sample such as a tissue sample. The labelling agents include nucleic acid-based probes (e.g., the primary probes disclosed herein and/or any detectable probe disclosed herein) and may comprise any of a variety of entities that can hybridize to a nucleic acid, typically by Watson-Crick base pairing, such as DNA, RNA, LNA, PNA, etc. The nucleic acid probes may comprise a hybridization region that is able to directly or indirectly bind to at least a portion of a target sequence in a target nucleic acid. The nucleic acid probe may be able to bind to a specific target nucleic acid (e.g., an mRNA, or other nucleic acids disclosed herein).

Specific probe designs can vary depending on the application and any suitable probe or probe set may be utilized and detected using the opto-fluidic instruments described herein. In some aspects, the probes or probe sets described herein, or intermediate probes (e.g., a secondary probe, and/or a higher order probe) can be selected from the group consisting of a circular probe, a circularizable probe, and a linear probe. In some embodiments, a circular probe is pre-circularized prior to hybridization to a target nucleic acid and/or one or more other probes. In some embodiments, a circularizable probe is circularized (e.g., by ligation) upon hybridization to a target nucleic acid and/or one or more other probes such as a splint. In some embodiments, a linear probe can be one that comprises a target recognition sequence and a sequence that does not hybridize to a target nucleic acid, such as a 5′ overhang, a 3′ overhang, and/or a linker or spacer (which may comprise a nucleic acid sequence, such a one or more barcode sequence, or a non-nucleic acid moiety). In some embodiments, the sequence (e.g., the 5′ overhang, 3′ overhang, and/or linker or spacer) is non-hybridizing to the target nucleic acid but may hybridize to one another and/or one or more other probes, such as detectably labeled probes.

In some embodiments, a primary probe, a secondary probe, and/or a higher order probe disclosed herein can comprise a padlock-like probe or probe set, such as one described) in U.S. Pat. No. 8,551,710, US 2020/0224244, US 2019/0055594, US 2021/0164039, US 2016/0108458, or US 2020/0224243, each of which is incorporated herein by reference in its entirety. Any suitable combination of the probe designs described herein can be used.

In some embodiments, the probes or probe sets described herein (e.g., a primary probe, or a secondary probe, and/or a higher order probe disclosed herein can comprise two or more parts. In some cases, a probe can comprise one or more features of and/or be modified based on: a split FISH probe or probe set described in WO 2021/167526A1 or Goh et al., “Highly specific multiplexed RNA imaging in tissues with split-FISH,” Nat Methods 17(7):689-693 (2020), which are incorporated herein by reference in their entireties; a Z-probe or probe set, such as one described in U.S. Pat. No. 7,709,198 B2, U.S. Pat. No. 8,604,182 B2, U.S. Pat. No. 8,951,726 B2, U.S. Pat. No. 8,658,361 B2, or Tripathi et al., “Z Probe, An Efficient Tool for Characterizing Long Non-Coding RNA in FFPE Tissues,” Noncoding RNA 4(3):20 (2018), which are incorporated herein by reference in their entireties; an HCR initiator or amplifier, such as one described in U.S. Pat. No. 7,632,641 B2, US 2017/0009278 A1, U.S. Pat. No. 10,450,599 B2, or Choi et al., “Third-generation in situ hybridization chain reaction: multiplexed, quantitative, sensitive, versatile, robust,” Development 145(12): dev165753 (2018), which are incorporated herein by reference in their entireties; a PLAYR probe or probe set, such as one described in US 2016/0108458 A1 or Frei et al., “Highly multiplexed simultaneous detection of RNAs and proteins in single cells,” Nat Methods 13(3):269-75 (2016), which are incorporated herein by reference in their entireties; a PLISH probe or probe set, such as one described in US 2020/0224243 A1 or Nagendran et al., “Automated cell-type classification in intact tissues by single-cell molecular profiling,” eLife 7:e30510 (2018), which are incorporated herein by reference in their entireties; a RollFISH probe or probe set such as one described in Wu et al., “RollFISH achieves robust quantification of single-molecule RNA biomarkers in paraffin-embedded tumor tissue samples,” Commun Biol 1, 209 (2018), which is hereby incorporated by reference in its entirety; a MERFISH probe or probe set, such as one described in US 2022/0064697 A1 or Chen et al., “Spatially resolved, highly multiplexed RNA profiling in single cells,” Science 348(6233): aaa6090 (2015), which are incorporated herein by reference in their entireties; a primer exchange reaction (PER) probe or probe set, such as one described in US 2019/0106733 A1, which is hereby incorporated by reference in its entirety.

In some instances, probes and/or probe sets are directly labeled with one or more detectable labels (e.g., an optically detectable label, such as a florescent moiety) that are detected on the opto-fluidic instruments disclosed herein. In other instances, probes and/or probe sets comprise a target binding region and one or more nucleic acid barcode sequences that identify the analyte. In these embodiments, the barcode sequence(s) may be detected on the opto-fluidic instruments disclosed herein to identify the analyte in the sample. In some instances, a probe or probe set disclosed herein is a circularizable probe or probe set (e.g., a padlock probe or padlock-like probe) comprising a barcode region comprising one or more barcode sequences.

The probes and/or probe sets describe herein may comprise any suitable number of barcode sequences. In some embodiments, the probes or probe sets may comprise 1, 2, 3, 4, 5, 6, 7, 8, 9, 10, 11, 12, 13, 14, 15 or more, 20 or more, 30 or more, 40 or more, or 50 or more barcode sequences. As an illustrative example, a first probe may contain a first target-binding sequence, a first barcode sequence, and a second barcode sequence, while a second, different probe may contain a second target-binding sequence (that is different from the first target-binding sequence in the first probe), the same first barcode sequence as in the first probe, but a third barcode sequence instead of the second barcode sequence. Such probes may thereby be distinguished by determining the various barcode sequence combinations present or associated with a given probe at a given location in a sample.

In some embodiments, a labelling agent may include analyte binding moiety that interacts with an analyte (e.g., a protein) in the sample (e.g., a cell or tissue sample) and a reporter oligonucleotide comprising one or more barcode sequences associated with the analyte and/or analyte binding moiety. For example, a labelling agent that is specific to one type of cell feature (e.g., a first protein) may have coupled thereto a first reporter oligonucleotide, while a labelling agent that is specific to a different cell feature (e.g., a second protein) may have a different reporter oligonucleotide coupled thereto. In some embodiments, an analyte binding moiety includes, but is not limited to, a protein, a peptide, an antibody (or an epitope binding fragment thereof), a lipophilic moiety (such as cholesterol), a cell surface receptor binding molecule, a receptor ligand, a small molecule, a bi-specific antibody, a bi-specific T-cell engager, a T-cell receptor engager, a B-cell receptor engager, a pro-body, an aptamer, a monobody, an affimer, a darpin, and a protein scaffold, or any combination thereof. For a description of exemplary labelling agents, reporter oligonucleotides, and methods of use, see, e.g., U.S. Pat. No. 10,550,429; U.S. Pat. Pub. 20190177800; and U.S. Pat. Pub. 20190367969, which are each incorporated by reference herein in their entirety.

In some embodiments, the nucleic acid probes, probe sets, reporter oligonucleotides, barcode sequences, etc. may be detected directly on the opto-fluidic instruments disclosed herein (e.g., primary probes comprise a detectable label, such as a florescent moiety), and/or by using secondary (or higher order) nucleic acid probes able to bind to the primary probes. In some embodiments, the nucleic acid probes (e.g., primary probes and/or secondary probes) are compatible with one or more biological and/or chemical reactions. For instance, a nucleic acid probe disclosed herein can serve as a template or primer for a polymerase (e.g., a circularized probe in a rolling circle amplification (RCA) reaction), a template or substrate for a ligase, a substrate for a click chemistry reaction, and/or a substrate for a nuclease (e.g., endonuclease or exonuclease for cleavage or digestion). In some instances, labelling agents (such as a primary probe set) are added to a biological sample (e.g., a cell or tissue sample) using the opto-fluidic instrument and subsequently detected using opto-fluidic instrument (e.g., using detectably labeled primary probes, sequential hybridization of detectable labelled oligonucleotides to primary probes, in situ sequencing (e.g., SBS, SBL, SBH), and the like). In some instances, labelling agents (such as a primary probe set) are added to a biological sample (e.g., a cell or tissue sample) outside the optofluidic instrument and the sample is loaded onto the opto-fluidic instruments disclosed herein for detection (e.g., using sequential hybridization of detectable labelled oligonucleotides, in situ sequencing (e.g., SBS, SBL, SBH), and the like).

In some embodiments, detection of the analytes, probes, probe sets, barcodes, etc. described herein can be performed in situ on the opto-fluidic instruments disclosed herein. In situ sequencing typically involves incorporation of a labeled nucleotide (e.g., fluorescently labeled mononucleotides or dinucleotides) in a sequential, template-dependent manner or hybridization of a labeled primer (e.g., a labeled random hexamer) to a nucleic acid template such that the identities (e.g., nucleotide sequence) of the incorporated nucleotides or labeled primer extension products can be determined, and consequently, the nucleotide sequence of the corresponding template nucleic acid. Aspects of in situ sequencing approaches are described, for example, in Mitra et al., “Fluorescent in situ sequencing on polymerase colonies” Anal. Biochem. 320, 55-65 (20030, and Lee et al., “Highly Multiplexed Subcellular RNA Sequencing in Situ” Science, 343(6177), 1360-1363 (2014). In addition, examples of methods and systems for performing in situ sequencing are described in US 2016/0024555, US 2019/0194709, and in U.S. Pat. Nos. 10,138,509, 10,494,662 and 10,179,932.

In some embodiments, sequencing can be performed by sequencing-by-synthesis (SBS). In some embodiments, a sequencing primer is complementary to sequences at or near the target to be detected (e.g., one or more barcode(s)). In such embodiments, sequencing-by-synthesis can comprise reverse transcription and/or amplification in order to generate a template sequence from which a primer sequence can bind. Exemplary SBS methods comprise those described for example, but not limited to, US 2007/0166705, US 2006/0188901, U.S. Pat. No. 7,057,026, US 2006/0240439, US 2006/0281109, US 2011/0059865, US 2005/0100900, U.S. Pat. No. 9,217,178, US 2009/0118128, US 2012/0270305, US 2013/0260372, and US 2013/0079232.

In some embodiments, sequence analysis of nucleic acids (e.g., nucleic acids such as RCA products comprising barcode sequences) can be performed by sequential hybridization (e.g., sequencing by hybridization and/or sequential in situ fluorescence hybridization). Sequential fluorescence hybridization can involve sequential hybridization of detection probes comprising an oligonucleotide and a detectable label. In some embodiments, a method disclosed herein comprises sequential hybridization of the detectable probes disclosed herein, including detectably labeled probes (e.g., fluorophore conjugated oligonucleotides) and/or probes that are not detectably labeled per se but are capable of binding (e.g., via nucleic acid hybridization) and being detected by detectably labeled probes. Exemplary methods comprising sequential fluorescence hybridization of detectable probes are described in US 2019/0161796, US 2020/0224244, US 2022/0010358, US 2021/0340618, and WO 2021/138676, MERFISH (described for example in Moffitt, et al., “Chapter One—RNA Imaging with Multiplexed Error-Robust Fluorescence In Situ Hybridization (MERFISH)”, Methods in Enzymology, 572, 1-49 (2016)), and hybridization-based in situ sequencing (HybISS) (described for example in Gyllborg et al., “Hybridization-based in situ sequencing (HybISS) for spatially resolved transcriptomics in human and mouse brain tissue,” Nucleic Acids Res 48(19):e112 (2020)) all of which are incorporated herein by reference.

In some embodiments, sequencing can be performed using sequencing by ligation (SBL). Such techniques utilize DNA ligase to incorporate oligonucleotides and identify the incorporation of such oligonucleotides. The oligonucleotides typically have different labels that are correlated with the identity of a particular nucleotide in a sequence to which the oligonucleotides hybridize. Aspects and features involved in sequencing by ligation are described, for example, in Shendure et al., “Accurate Multiplex Polony Sequencing of an Evolved Bacterial Genome,” Science, 309: 1728-1732 (2005), and in U.S. Pat. Nos. 5,599,675; 5,750,341; 6,969,488; 6,172,218; and 6,306,597. Exemplary techniques for in situ SBL comprise, but are not limited to, STARmap (described for example in Wang et al., “Three-dimensional intact-tissue sequencing of single-cell transcriptional states,” Science, 361(6499) 5691 (2018)) and US 2021/0164039).

In some embodiments, probe barcodes (e.g., plurality of probes or probe sets comprising one or more barcode sequences) or complements or products thereof are targeted by detectably labeled detection oligonucleotides, such as fluorescently labeled oligonucleotides. In some embodiments, one or more decoding schemes (e.g., sequential rounds of fluorescent probe hybridization) are used on the opto-fluidic instruments disclosed herein to decode the signals, such as fluorescence, for sequence identification. In any of the embodiments herein, barcodes (e.g., primary and/or secondary barcode sequences) can be analyzed (e.g., detected or sequenced using the opto-fluidic instruments disclosed herein) using any suitable methods or techniques, comprising those described herein, such as RNA sequential probing of targets (RNA SPOTs), sequential fluorescent in situ hybridization (seqFISH), single-molecule fluorescent in situ hybridization (smFISH), multiplexed error-robust fluorescence in situ hybridization (MERFISH), hybridization-based in situ sequencing (HybISS), in situ sequencing, targeted in situ sequencing, fluorescent in situ sequencing (FISSEQ), or spatially-resolved transcript amplicon readout mapping (STARmap). In some embodiments, the methods provided herein comprise analyzing the barcodes by sequential hybridization and detection with a plurality of labelled probes (e.g., detection oligonucleotides or detectable probes). Exemplary decoding schemes are described in Eng et al., “Transcriptome-scale Super-Resolved Imaging in Tissues by RNA SeqFISH+,” Nature 568(7751):235-239 (2019); Chen et al., Science; 348(6233):aaa6090 (2015); Gyllborg et al., Nucleic Acids Res (2020) 48(19):e112; U.S. Pat. No. 10,457,980 B2; US 2016/0369329 A1; WO 2018/026873 A1; and US 2017/0220733 A1, all of which are incorporated by reference in their entirety. In some embodiments, these assays enable signal amplification, combinatorial decoding, and error correction schemes at the same time.

It is to be noted that, although the above discussion relates to an opto-fluidic instrument that can be used for in situ target molecule detection via probe hybridization, the discussion herein equally applies to any opto-fluidic instrument that employs any imaging or target molecule detection technique. That is, for example, an opto-fluidic instrument may include a fluidics module that includes fluids applied for establishing the experimental conditions used for the probing of target molecules in the sample. Further, such an opto-fluidic instrument may also include a sample module configured to receive the sample, and an optics module including an imaging system for illuminating (e.g., exciting one or more fluorescent probes within the sample) and/or imaging light signals received from the probed sample. The opto-fluidic instrument may also include other ancillary modules configured to facilitate the operation of the opto-fluidic instrument, such as, but not limited to, cooling systems, motion calibration systems, etc.

In various embodiments, the techniques for detecting target molecules in a sample may include a process where a reagent entraining the detection probes is dispensed on a sample device supporting the sample to allow the probing of the target molecules by the probes. In some instances, the reagents/probes as well as the condition for the probing of target molecules in the sample by the probes may be temperature sensitive. That is, for example, the probes may have to be maintained at a suitable temperature or temperature range for the probes to be effective in probing the target molecules. Further, the target molecule probing process itself may have to occur at a suitable temperature or temperature range for the process to be effective.

In addition, some of the modules of the opto-fluidic instrument may generate a substantial amount of heat when in operation. For example, the imaging system that images the probed sample may be a fluorescence imaging system having a camera that is configured to capture or image fluorescence released by the probes when the probes are excited by light from light sources (e.g., LEDs). In such cases, the light sources and the camera may generate a significant amount of heat that may raise the temperature of the opto-fluidic instrument as a whole (e.g., including the reagents, the sample, etc.).

Accordingly, there exists a need for methods and systems for controlling the temperature of various modules of the opto-fluidic instrument so as to facilitate the target molecules detection operations of the opto-fluidic instrument. For example, the methods and systems may allow for cooling the heat sources in the optics module of the opto-fluidic instrument, such as the camera and the light sources that excite the probes. Further, the method and systems may allow for controlling the temperature of the reagent decks in the fluidics module of the opto-fluidic instrument where the reagents are stored, as well as the temperature of the sample module supporting the sample that includes the to-be-detected target molecules. In various embodiments, the methods and systems facilitate the circulation of coolants to the various modules of the opto-fluidic instrument to allow heat exchange therewith to control the temperatures of the modules.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### II. Example Descriptions of Terms

As used herein the specification, “a” or “an” may mean one or more. As used herein in the claim(s), when used in conjunction with the word “comprising,” the words “a” or “an” may mean one or more than one. Some embodiments of the disclosure may consist of or consist essentially of one or more elements, method steps, and/or methods of the disclosure. It is contemplated that any method or composition described herein can be implemented with respect to any other method or composition described herein and that different embodiments may be combined.

As used herein, “substantially” means sufficient to work for the intended purpose. The term “substantially” thus allows for minor, insignificant variations from an absolute or perfect state, dimension, measurement, result, or the like such as would be expected by a person of ordinary skill in the field but that do not appreciably affect overall performance. When used with respect to numerical values or parameters or characteristics that can be expressed as numerical values, “substantially” means within ten percent.

The use of the term “or” in the claims is used to mean “and/or” unless explicitly indicated to refer to alternatives only or the alternatives are mutually exclusive, although the disclosure supports a definition that refers to only alternatives and “and/or.” For example, “x, y, and/or z” can refer to “x” alone, “y” alone, “z” alone, “x, y, and z,” “(x and y) or z,” “x or (y and z),” or “x or y or z.” It is specifically contemplated that x, y, or z may be specifically excluded from an embodiment. As used herein “another” may mean at least a second or more. The term “ones” means more than one.

As used herein, the term “plurality” can be 2, 3, 4, 5, 6, 7, 8, 9, 10, or more.

As used herein, the term “set of” means one or more. For example, a set of items includes one or more items.

As used herein, the phrase “at least one of,” when used with a list of items, means different combinations of one or more of the listed items may be used and only one of the items in the list may be needed. The item may be a particular object, thing, step, operation, process, or category. In other words, “at least one of” means any combination of items or number of items may be used from the list, but not all of the items in the list may be required. For example, without limitation, “at least one of item A, item B, or item C” means item A; item A and item B; item B; item A, item B, and item C; item B and item C; or item A and C. In some cases, “at least one of item A, item B, or item C” means, but is not limited to, two of item A, one of item B, and ten of item C; four of item B and seven of item C; or some other suitable combination

As used herein, the term “about” refers to include the usual error range for the respective value readily known. Reference to “about” a value or parameter herein includes (and describes) embodiments that are directed to that value or parameter per se. For example, description referring to “about X” includes description of “X”. In some embodiments, “about” may refer to ±15%, ±10%, ±5%, or ±1% as understood by a person of skill in the art.

As used herein, the term “fluidic connection”, or variants thereof, refer to the connection of two or more components by tubes that allow fluids to flow therein from one of the two or more components to another. The fluid flow can be uni-directional or bi-directional.

As used herein, in some instances, the term “thermal coupling”, or variants thereof, refer to configurations of two or more components that allow heat to be exchanged with each other (e.g., such that the temperature of one or both of them increases or decreases), or for a component (e.g., a sensor) to be capable of detecting the temperature of the other components to which the component is thermally coupled.

While the present teachings are described in conjunction with various embodiments, it is not intended that the present teachings be limited to such various embodiments. On the contrary, the present teachings encompass various alternatives, modifications, and equivalents, as will be appreciated by those of skill in the art.

In describing the various embodiments, the specification may have presented a method and/or process as a particular sequence of steps. However, to the extent that the method or process does not rely on the particular order of steps set forth herein, the method or process should not be limited to the particular sequence of steps described, and one skilled in the art can readily appreciate that the sequences may be varied and still remain within the spirit and scope of the various embodiments.

### III. Opto-Fluidic Instruments for Analysis of Biological Samples

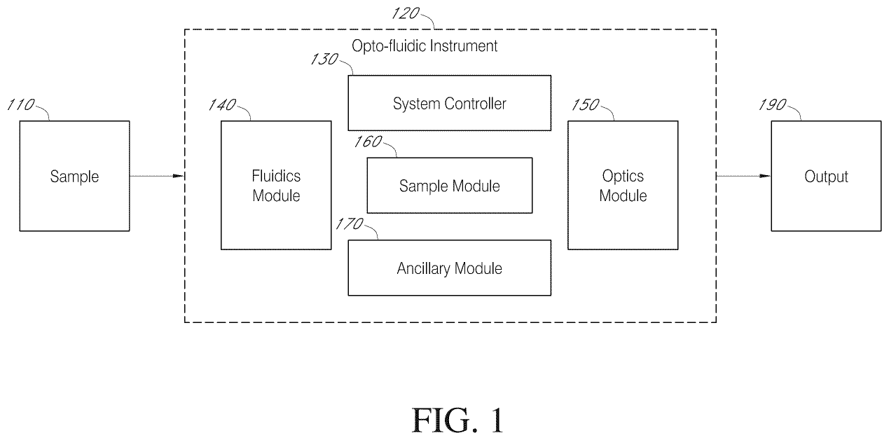

FIG. 1 shows an example workflow of analysis of a biological sample 110 (e.g., cell or tissue sample) using an opto-fluidic instrument 120, according to various embodiments. In various embodiments, the sample 110 can be a biological sample (e.g., a tissue) that includes molecules targeted for analysis (i.e., target molecules), such as DNA, RNA, proteins, antibodies, etc. In various embodiments, the biological sample is a fresh frozen tissue. In various embodiments, the biological sample is a formalin-fixed paraffin-embedded (FFPE) sample. For example, the sample 110 can be a sectioned tissue that is treated to access the RNA thereof for labeling with circularizable DNA probes. In various embodiments, ligation of the probes generates a circular DNA probe which can be enzymatically amplified and bound with fluorescent oligonucleotides, to produce a sufficiently bright signal that facilitates image acquisition and has a high signal-to-noise ratio.

In various embodiments, the sample 110 may be placed in the opto-fluidic instrument 120 for analysis and detection of the target molecules in the sample 110. In various embodiments, the opto-fluidic instrument 120 is configured to facilitate the experimental conditions conducive for the detection of the target molecules. For example, the opto-fluidic instrument 120 can include a fluidics module 140, an optics module 150, a sample module 160, and at least one ancillary module 170, and these modules may be operated by a system controller 130 to create the experimental conditions for the probing of the target molecules in the sample 110 by selected probes (e.g., circularizable DNA probes), as well as to facilitate the imaging of the probed sample (e.g., by an imaging system of the optics module 150). In various embodiments, the various modules of the opto-fluidic instrument 120 may be separate components. In various embodiments, the various modules of the opto-fluid instrument may be in electrical communication with each other. In various embodiments, at least some of the modules of the opto-fluidic instrument 120 may be integrated together into a single module.

In various embodiments, the sample module 160 may be configured to receive the sample 110 in the opto-fluidic instrument 120. For instance, the sample module 160 may include a sample interface module (SIM) that is configured to receive a sample device (e.g., cassette) in which a substrate (having the sample 110 positioned thereon) can be secured. In various embodiments, the substrate is a glass slide. That is, the sample 110 may be placed in the Opto-fluidic instrument 120 by securing the substrate having the sample 110 (e.g., the sectioned tissue) within the sample device that is then inserted into the SIM of the sample module 160. In various embodiments, the SIM includes an alignment mechanism configured to secure the sample device within the SIM and align the sample device in X, Y, and Z axes within the SIM. In some instances, the sample module 160 may also include an X-Y stage onto which the SIM is mounted. The X-Y stage may be configured to move the SIM mounted thereon (e.g., and as such the sample device containing the sample 110 inserted therein) in perpendicular directions along a two-dimensional (2D) plane of the Opto-fluidic instrument 120. Additional discussion related to the SIM can be found in US Nonprovisional application Ser. No. 18/328,200, filed Jun. 2, 2023 Jun. 3, 2022, titled “Methods, Systems, and Devices for Sample Interface,” which is incorporated herein by reference in its entirety.

The experimental conditions that are conducive for the detection of the target molecules in the sample 110 may depend on the target molecule detection technique that is employed by the Opto-fluidic instrument 120. For example, in various embodiments, the Opto-fluidic instrument 120 can be a system that is configured to detect molecules in the sample 110 via hybridization of probes. In such cases, the experimental conditions can include molecule hybridization conditions that result in the intensity of hybridization of the target molecule (e.g., nucleic acid) to a probe (e.g., oligonucleotide) being significantly higher when the probe sequence is complementary to the target molecule than when there is a single-base mismatch. The hybridization conditions include the preparation of the sample 110 using reagents such as washing/stripping reagents, probe reagents, etc., and such reagents may be provided by the fluidics module 140. Examples of the washing buffer include but are not limited to deionized water, phosphate-buffered saline (PBS), PBS with dimethyl sulfoxide (DMSO), and/or the like. The stripping buffer can be but is not limited to DMSO, a surfactant, and/or the like. In some instances, the surfactant can be or include polysorbate 20. In some instances, the stripping buffer may include the surfactant in a weight proportion of about 0.1%. The probe reagent can be fluorescent probes, such as but not limited to oligonucleotide probes.

In various embodiments, the fluidics module 140 may include one or more components that may be used for storing the reagents, as well as for transporting said reagents to and from the sample device containing the sample 110. For example, the fluidics module 140 may include one or more reservoirs configured to store the reagents, as well as a waste container configured for collecting the reagents (e.g., and other waste) after use by the Opto-fluidic instrument 120 to analyze and detect the molecules of the sample 110. In various embodiments, the one or more reservoirs include one or more high use reagent reservoirs. In various embodiments, the fluidics module 140 may be configured to receive one or more low use reagent plates (e.g., a 96 deep well plate). Further, the fluidics module 140 may also include pumps, tubes, pipettes, etc., that are configured to facilitate the transport of the one or more reagents (e.g., high use reagent and/or low use reagent) to the sample device and thus contact the sample 110 with the reagent (e.g., high use reagent and/or low use reagent). For instance, the fluidics module 140 may include one or more pumps (“reagent pumps”) that are configured to pump washing and/or stripping reagents to the sample device for use in washing/stripping the sample 110. In various embodiments, the fluidics module 140 may be configured for other washing functions such as washing an objective lens of the imaging system of the optics module 150. In some cases, a stage (e.g., a Y-Z stage) may be configured to move the pipettes along one or more directions, to and from the sample device containing the sample 110, so that the various reagents may be dispensed in the sample device, and spent reagents may be extracted from the sample device.

In various embodiments, the ancillary module 170 includes a cooling system (i.e. a heat transfer system) of the Opto-fluidic instrument 120. In various embodiments, the cooling system includes a network of coolant-carrying tubes configured to transport coolant to various modules of the Opto-fluidic instrument 120 for regulating the temperatures thereof. In such cases, the ancillary module 170 may include one or more heat transfer components of a heat transfer circuit. In various embodiments, the heat transfer components include one or more coolant reservoirs for storing coolants and pumps (e.g., “coolant pumps”) for generating a pressure differential, thereby forcing the coolants to flow from the reservoirs to the various modules of the Opto-fluidic instrument 120 via the coolant-carrying tubes. In some instances, the heat transfer components of the ancillary module may include returning coolant reservoirs that may be configured to receive and store returning coolants, i.e., heated coolants flowing back into the returning coolant reservoirs after absorbing heat discharged by the various modules of the Opto-fluidic instrument 120. In such cases, ancillary module 170 may also include one or more cooling fans that are configured to force air (e.g., cool and/or ambient air) to the external surfaces of the returning coolant reservoirs to thereby cool the heated coolant(s) stored therein. In some instance, the ancillary module 170 may also include one or more cooling fans that are configured to force air directly to one ore more components of the Opto-fluidic instrument 120 so as to cool said one or more components. For example, the ancillary module 170 may include cooling fans that are configured to directly cool by forcing ambient air past the system controller 130 to thereby cool the system controller 130.

As discussed above, the Opto-fluidic instrument 120 may include an optics module 150 which include the various optical components of the Opto-fluidic instrument 120, such as but not limited to a camera, an illumination module (e.g., including on or more LEDs and/or one or more lasers), an objective lens, and/or the like. The optics module 150 may include a fluorescence imaging system that is configured to image the fluorescence emitted by the probes (e.g., oligonucleotides) in the sample 110 after the probes are excited by light from the illumination module of the optics module 150.

In various embodiments, the system controller 130 may be configured to control the operations of the Opto-fluidic instrument 120 (e.g., and the operations of one or more modules thereof). In some instances, the system controller 130 may take various forms, including a processor, a single computer (or computer system), or multiple computers in communication with each other. In various embodiments, the system controller 130 may be communicatively coupled with a data storage, a set of input devices, a display system, or a combination thereof. In various embodiments, some or all of these components may be considered to be part of or otherwise integrated with the system controller 130, may be separate components in communication with each other, or may be integrated together. In other embodiments, the system controller 130 can be, or may be in communication with, a cloud computing platform.

In various embodiments, the Opto-fluidic instrument 120 may analyze the sample 110 and generate the output 190 that includes indications of the presence of the target molecules in the sample 110. For instance, with respect to the example embodiment discussed above where the Opto-fluidic instrument 120 employs a hybridization technique for detecting molecules, the Opto-fluidic instrument 120 may perform a plurality of probing rounds on the sample 110. During the plurality of probing rounds, the sample 110 undergoes successive rounds of fluorescent probe hybridization (using two or more sets of fluorescent probes, where each set of fluorescent probes is excited by a different color channel) and is volumetrically imaged in a plurality of z-stacks to detect target molecules in the probed sample 110 in three dimensions. In such cases, the output 190 may include a plurality of light signals at specific three-dimensional locations over the plurality of probing cycles. In various embodiments, an optical signature (e.g., a codeword) specific to each gene is determined from the detected optical signals at each three-dimensional location across the plurality of probing cycles, which allows the identification of the target molecules.

### IV. Heat Exchange Systems for Temperature Control of Opto-Fluidic Instruments

In various embodiments, one or more modules (e.g., the optics module) of an opto-fluidic instrument generate waste heat that contributes to an increase in the temperature of the opto-fluidic instrument (as a whole and/or of other modules within the instrument). For example, the optics module may include a camera module, an illumination module, etc., for use in imaging samples that are probed with fluorescent probes configured to detect the presence of target molecules therein. In various embodiments, the imaging system of the optics module is a fluorescence imaging system (e.g., epifluorescence) that includes an illumination module including LED light sources configured to excite the probes in the sample. Further, the fluorescence imaging system may also include a camera module for capturing fluorescence released by the probes in the sample when excited by light from the light sources. Such modules (e.g., the illumination module, the camera module, etc.), however, tend to generate heat when the opto-fluidic instrument is in operation. In various embodiments, a single experiment lasts one or more days and thus, the various modules of the opto-fluidic instrument may generate heat over substantially this entire time frame. For example, the camera module and the illumination module of the opto-fluidic instrument generate heat, when the opto-fluidic instrument is in operation, that can raise each module's temperature to a range from about 30° C. to about 80° C., or even higher. Such a high temperature may interfere with the functions of the opto-fluidic instrument, and thus, a heat exchange system may be used to control the temperatures (e.g., draw waste heat away from via conduction and/or convection) of such modules. For example, components of the optics module (such as the objective lens, camera, or LEDs) may have optimal operating temperatures, and excessive heating of those components may cause the components to have suboptimal performance (e.g., causing distortion in the images of the sample, degraded performance or failure of a component, etc.).

In various embodiments, one or more modules of the opto-fluidic instrument (e.g., the sample module) may include one or more thermoelectric coolers (TECs) that are used to cool components of the module. For example, the SIM of the sample module includes a TEC configured to cool a sample positioning plate onto which a sample device is placed. In another example, the reagent deck includes a plurality of TECs (e.g., four per reagent 96-well plate). In various embodiments, waste heat from the hot side of the TECs may be transferred to the heat exchange system to allow for improved performance of the TECs.

In various embodiments, a heat exchange system is used to control the temperatures (e.g., draw waste heat away from via conduction and/or convection) of the SIM of the sample module and/or the probe reagents of the opto-fluidic instrument. In some embodiments, one or more (e.g., all) reagents (e.g., low use reagents, such as probe reagents) are stored in a reagents deck, from which the reagents may be retrieved for dispensing into a sample device that holds the sample. That is, a substrate (e.g. a glass slide) having the sample (that includes the target molecules) positioned thereon may be secured in a sample device (e.g., a cassette), which in turn is received by a SIM that is configured to support the sample device (which secures a substrate having the sample positioned thereon) and facilitate the target molecule(s) detection processes (e.g., based on probe hybridization or SBH). In such cases, the target molecules detection processes can include the dispensation of the probe reagents (e.g., fluorescently tagged oligonucleotide probes) into the sample device such that the target molecules can be probed by the probes in the probe reagents.

In various embodiments, the probe reagents and/or the probing of the target molecules by the probes are temperature-dependent, and the temperatures of the same may have to be controlled to facilitate successful detection of target molecules. For example, a temperature of the reagents deck storing the probe reagents is maintained at low temperatures (but not below freezing). In various embodiments, the reagents deck is maintained at a temperature of between about 0° C. and about 10° C., including values and subranges therebetween. In various embodiments, the reagents deck is maintained at temperature below about 10° ° C., below about 5° C., below about 3° C., etc. In various embodiments, the reagents deck is maintained within a temperature range via one or more TECs (e.g., using closed loop control). In various embodiments, the heat exchange system is thermally coupled to (e.g., in contact with) the hot side of each TEC of the reagent deck. In various embodiments, the cold side of the TECs provide cooling to the reagents. In various embodiments, a temperature of the SIM supporting the sample is maintained (e.g., via closed loop control using a TEC) such that the sample has a suitable temperature to facilitate the probing of the target molecules. In such cases, the afore-mentioned heat exchange system may also be utilized to cool the hot side of one or more TECs used to cool the SIM and/or the reagents deck. That is, an integrated heat exchange system may be utilized to control the temperatures of a SIM, a reagents deck, a camera module and an illumination module of the opto-fluidics instrument.

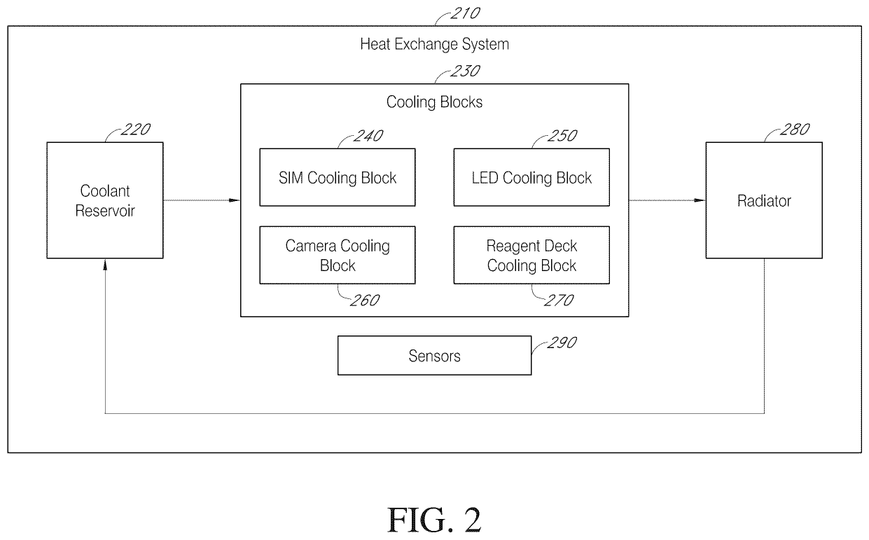

FIG. 2 shows a schematic of a heat exchange system for controlling the temperatures of modules of an in-situ analysis system, according to various embodiments. In various embodiments, the heat exchange system 210 can be a component of the or represent the entire ancillary module 170 of FIG. 1. In some instances, the heat exchange system 210 includes a coolant reservoir 220 that is configured to store a working fluid (e.g., a coolant). In some cases, the working fluid is a liquid coolant. For example, the coolant can include water, deionized water (DI water), an ethylene glycol-based coolant, a propylene glycol-based coolant, and/or a mixture thereof. In various embodiments, propylene glycol-based coolants may be utilized in particular for long term galvanic corrosion mitigation along with biological growth mitigation and ability to handle low shipping temperatures. In various embodiments, propylene glycol-based coolants may be utilized in particular for more-permissive disposal regulations. In cases where the coolant is a liquid coolant, the coolant reservoir 220 includes a sensor (e.g., a liquid level sensor) that is configured to measure an amount of the coolant remaining in the coolant reservoir 220. That is, one of the sensors 290 of the heat exchange system 210 may be the liquid level sensor that is configured to measure the level of coolant in the coolant reservoir 220. In various embodiments, the coolant can be an air coolant. In such cases, one of the sensors 290 can be a sensor (e.g., such as air pressure sensor) that is configured to determine the amount of air remaining in the coolant reservoir 220. In various embodiments, the coolant can be a fluid cooled to a desired temperature (e.g., room temperature, below about 10° C., about 5° C., about 3 ºC, including values and subranges therebetween).

In various embodiments, the heat exchange system 210 includes a pump that is configured to pump the coolant stored in the coolant reservoir through the various modules of the opto-fluidic instrument, such as the SIM, the reagents deck, the camera module and the illumination module, and to the radiator 280, where the heat drawn away from the various modules is exchanged (e.g., with ambient air). In various embodiments, the SIM includes one or more TEC. In various embodiments, the reagent deck includes one or more TEC. In various embodiments, the heat exchange system is configured to cool (e.g., via conduction and/or convection) a hot side of a TEC.

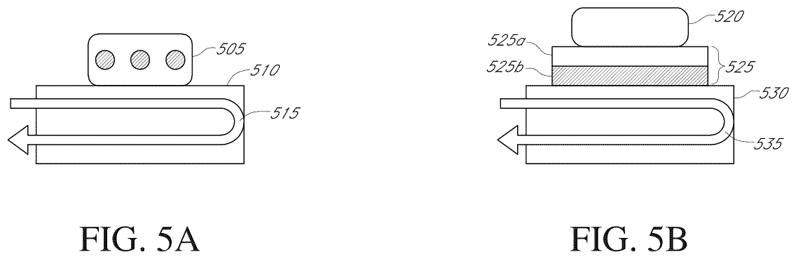

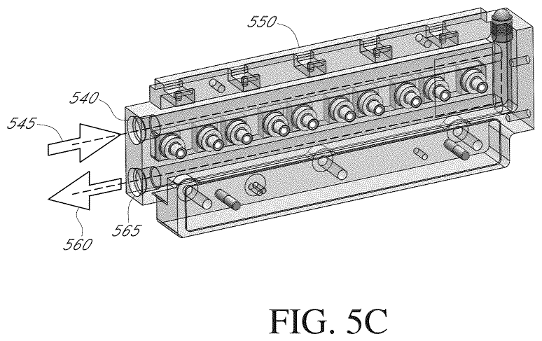

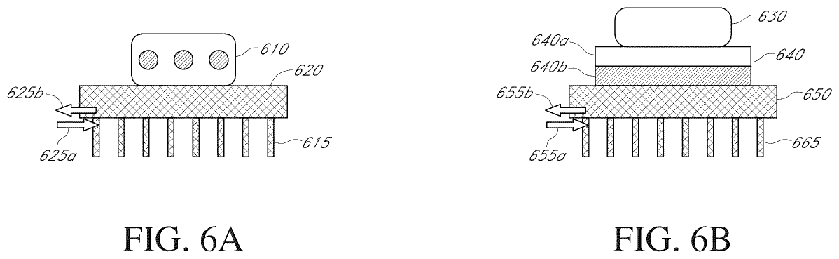

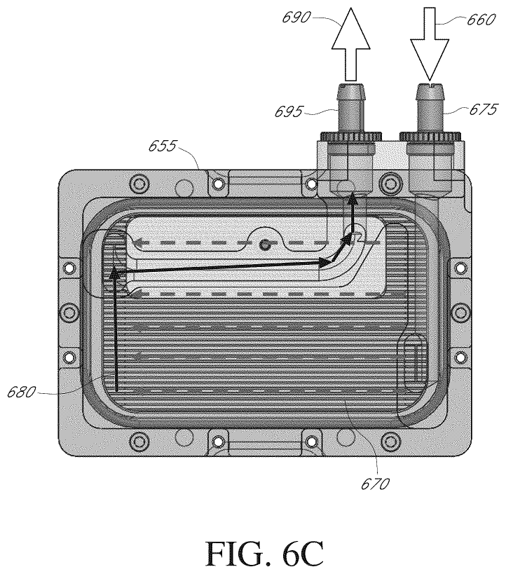

In various embodiments, the heat exchange system 210 may include multiple cooling blocks 230 of modules of the opto-fluidic instrument. In various embodiments, the cooling blocks 230 may be configured to receive the coolant from the coolant reservoir 220, where the received coolant absorbs heat from the respective modules of the cooling blocks 230. For example, the afore-mentioned modules of the opto-fluidic instrument, e.g., the SIM, the illumination module, the camera module, and the reagents deck may have associated therewith a SIM cooling block 240, a LED cooling block 250, a camera cooling block 260, and a reagent deck cooling block 270, respectively. In some embodiments, the respective cooling blocks 230 of the modules may be configured to receive heat from the modules (e.g., via conduction) and transfer the absorbed heat to the flowing coolant as the coolant is received by the module. For example, as discussed below in more detail with reference to FIGS. 5A-5C and 6A-6C, the cooling block 230 may include one or more heat sinks that are thermally coupled to their respective modules and as such configured to absorb heat from the respective modules. In such cases, the coolant received at a module may come into thermal contact with the respective cooling blocks 230 of the module such that the heat from the cooling block 230 is absorbed by flowing the coolant, thereby increasing the temperature of the coolant as the coolant flows through each cooling block. The coolant may then flow out of the cooling block 230 (e.g., and the respective module), resulting in the lowering of that module's temperature.

In various embodiments, the SIM of the opto-fluidic instrument has a sample positioning plate onto which a sample device (e.g., a cassette that is configured to receive and secure a substrate having a sample positioned thereon) may be placed. In some instances, the sample device forms a well around the sample and may also receive reagents (e.g., probe reagents, imaging buffer, washing buffer, stripping buffer) in the well. In various embodiments, the SIM cooling block 240 is thermally coupled to a TEC. In various embodiments, the SIM cooling block 240 is in contact with the hot side of a TEC and the cold side of the TEC is in contact with the sample positioning plate. In various embodiments, the SIM cooling block 240 may include a heat sink that is positioned in proximity to the sample positioning plate such that the heat sink may be thermally coupled to (e.g., in thermal communication with) the sample in the sample device. In various embodiments, the SIM cooling block 240 is configured to receive the coolant from the coolant reservoir 220 and allow the coolant to circulate through the heat sink to thereby draw heat away from the heat sink. In embodiments where the heat sink includes fins, the coolant can be flowed through the fins of the heat sink to thereby draw heat away from the fins. In such cases, the heat sink, being in thermal communication with one or more thermoelectric cooler (TEC), absorbs heat from the hot side of the one or more TEC and releases the absorbed heat to the coolant circulating in the heat sink, thereby lowering the temperature of the one or more TEC in the SIM (while the one or more TEC maintains the sample at a desired temperature).

In various embodiments, the reagent deck of the opto-fluidic instrument includes one or more reagent plates storing reagents (e.g., probe reagents). In various embodiments, the reagent deck cooling block 270 includes one or more TECs thermally coupled with the reagent well plate and, thus, the reagents stored in the reagent well plate. In various embodiments, the reagent deck cooling block 270 includes a heat sink that is positioned in proximity to the one or more TECs such that the heat sink is thermally coupled to (e.g., in thermal communication with) the hot side of one or more TEC. In various embodiments, the reagent deck cooling block 270 is configured to receive the coolant from the coolant reservoir 220 and allow the coolant to circulate along and/or between the fins of the heat sink. In such cases, the heat sink, being in thermal communication with the TEC, may absorb heat from the hot side of the one or more TEC and transfer the absorbed heat to the coolant circulating in the heat sink, thereby lowering the temperature of the one or more TEC in the reagent plates (while the one or more TEC maintains the reagents at a desired temperature).

In various embodiments, the camera module and/or the illumination module of the opto-fluidic instrument generate heat when in operation. In various embodiments, the camera cooling block 260 or the LED cooling block 250 includes a heat sink that is positioned in proximity to the camera module or the illumination module, respectively, such that the heat sink may be thermally coupled to, and be configured to absorb heat generated by, the respective module (e.g., the camera module and/or the illumination module). In various embodiments, the heat sink may include one or more fins. In various embodiments, the heat sink may include a fluid path configured to flow coolant through and draw away heat from the camera and/or LEDs. In various embodiments, to improve heat transfer, the coolant may flow along and/or between one or more fins of the heat sink. In various embodiments, the reagent deck cooling block 270 or the LED cooling block 250 may be configured to receive the coolant from the coolant reservoir 220 and allow the coolant to circulate in the heat sink. In such cases, the coolant that is circulating in the heat sink may absorb the heat from the heat sink, thereby effectively lowering the temperature of the camera module or the illumination module.

In various embodiments, the heat exchange system 210 includes a radiator 280 configured to receive the heated coolant from the afore-mentioned modules (e.g., or respective cooling blocks 230) of the opto-fluidic instrument for cooling therein. For example, as discussed above, a pump may force the coolant in the coolant reservoir 220 to flow towards the cooling blocks 230 of the modules of the opto-fluidic instrument, where the coolant may be heated after undergoing heat exchange with the cooling blocks 230. In various embodiments, heated coolant flows to the radiator 280. In some instances, the radiator 280 include one or more cooling fans configured to force ambient or cool air into the radiator, thereby cooling the heated coolant that is received from the cooling blocks 230. In various embodiments, the radiator 280 includes one or more heat sinks through which the ambient or cooled air flows. In various embodiments, the cooled coolant is returned from the radiator 280 back to the coolant reservoir 220 for further use in controlling the temperatures of the modules of the opto-fluidic instrument. In some instances, the transport of the cooled coolant from the radiator 280 to the coolant reservoir 220, as well the transport of the coolant from the coolant reservoir 220 to the radiator 280 (e.g., via the modules and/or cooling blocks 230 of the opto-fluidic instrument) may be via fluidic paths established by tubing (e.g., plastic tubing).

In various embodiments, the heat exchange system 210 includes sensors 290, which may include the liquid level sensor of the coolant reservoir 220 as discussed above. In some instances, the sensors 290 may also include temperature sensors and/or flow rate sensors that are disposed along the fluid paths transporting the coolants therein between the coolant reservoir 220, the radiator 280, the modules of the opto-fluidic instrument (e.g., including the cooling blocks 230). In various embodiments, the temperature sensors and/or the flow rate sensors disposed on the fluid paths are configured to measure the temperature or the flow rate, respectively, of the coolants flowing in the fluid paths. In some instances, the sensors 290 may also include temperature sensors that are thermally coupled to the modules of the opto-fluidic instrument (e.g., including the cooling blocks 230). In various embodiments, the temperature sensors may be configured to measure the temperatures of the modules, and/or components thereof. For example, a temperature sensor that is thermally coupled to the illumination module may be configured to measure the temperature of the LEDs, the LED cooling blocks, etc., of the illumination module. In some instances, the temperature sensor can be a thermistor, a thermocouple, a resistive temperature detector, or a semiconductor-based temperature sensor. In various embodiments, the flow rate sensor can be a Coriolis flow meter, a differential pressure flow meter, a magnetic flow meter, a multiphase flow meter, an ultrasonic flow meter, or a vortex flow meter.

### V. Example Implementation of Heat Exchange Systems in Opto-Fluidic Instruments

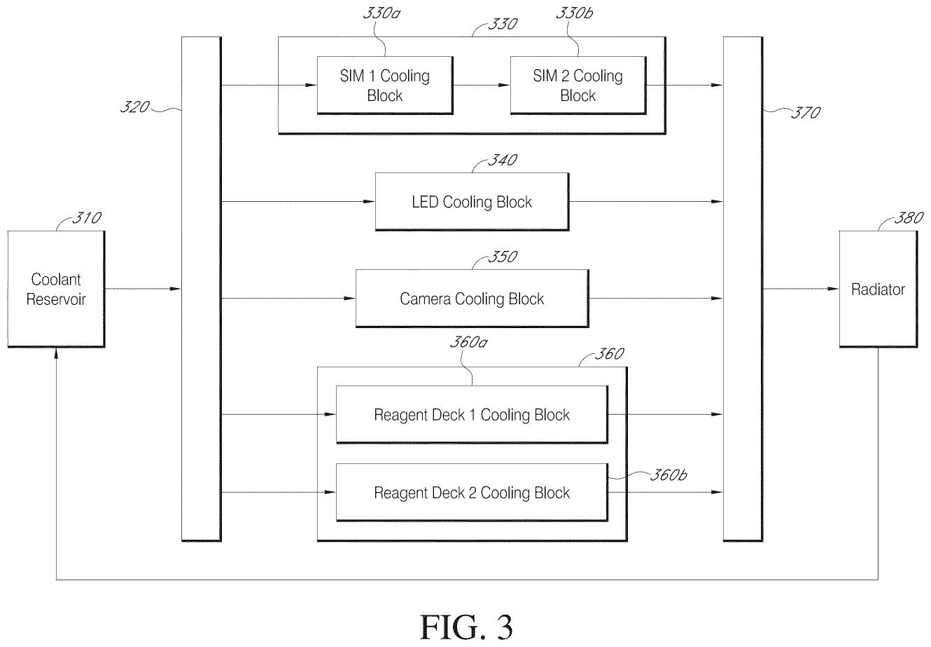

In various embodiments, the fluidic paths of the heat exchange system 210 connect the cooling blocks 230 in series, in parallel, or combination thereof, as shown in the non-limiting example schematic of FIG. 3. For example, in some instances, the SIM cooling block 330, the LED cooling block 340, the camera cooling block 350, and the reagent deck cooling block 360 are fluidically connected in parallel. In various embodiments, an opto-fluidic instrument can include multiple of any type of cooling block. In various embodiments, the SIM cooling block 330 may include multiple SIM cooling blocks, SIM 1 cooling block 330a and SIM 2 cooling block 330b, which may be fluidically connected to each other in series. In various embodiments, the multiple cooling blocks of a given module, such as reagent deck 1 cooling block 360a and reagent deck 2 cooling block 360b may be fluidically connected to each other in parallel. It is to be understood that the fluidic connection configuration shown in FIG. 3 is a non-limiting example illustration and that it is contemplated that the cooling blocks may be fluidically connected to each other in any suitable arrangement of modules in series and/or in parallel. For example, the SIM cooling block 330, the LED cooling block 340, the camera cooling block 350, and the reagent deck cooling block 360 may be fluidically connected in series, or in a combination of in series and in parallel.

In various embodiments, a pump of the heat exchange system may direct (e.g., via one or more pumps) the coolant in the coolant reservoir 310 to flow to the splitting manifold 320, which may in turn direct the received coolant to multiple fluid paths that are connected to each other in parallel. For example, the splitting manifold 320 receives coolant from the coolant reservoir 310 and splits the coolant flow into five fluid paths that are connected in parallel. The five fluid paths separately transport the coolant to the SIM 1 cooling blocks 330a, the LED cooling block 340, the camera cooling block 350, the reagent deck 1 cooling block 360a, and the reagent deck 2 cooling block 360b. In some instances, a flow restrictor may be disposed on each fluid path to control the flow rate of the coolant flowing therein. The flow restrictors disposed on the different fluid paths may be the same or different.

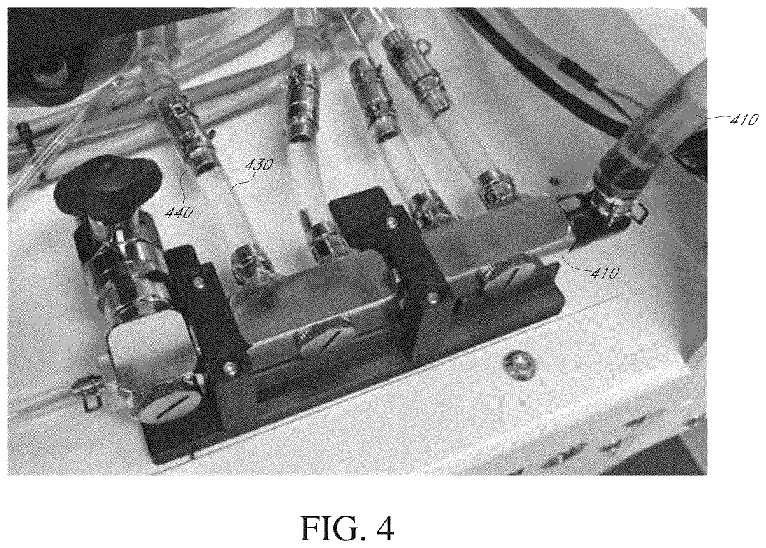

That is, for example, the flow restrictors on any two of the fluid paths may be the same (e.g., and as such the flow rates of the coolant therein may be the same or substantially the same) or different (e.g., and as such the flow rates of the coolant therein may be different). For instance, the flow restrictor can be an orifice, and the orifices on two different fluid paths may have the same or substantially the same diameter (e.g., causing the coolant in the two fluid paths to have the same or substantially the same flow rates). In other cases, the orifices on the two different fluid paths may have different diameters (e.g., causing the coolants in the two fluid paths to have different flow rates). FIG. 4 shows an example illustration of the use of a splitting manifold 420 to split coolant flow 410 received from coolant reservoir into five fluid paths 430 transporting the coolant to the afore-mentioned cooling blocks, according to various embodiments. Same or different sized flow restrictors 440 may be disposed on the fluid paths 430 to control the flow rate of the coolant flowing therein.

Returning to FIG. 3, in various embodiments, the coolants distributed by the splitting manifold 320 may flow into the respective cooling blocks and exchange heat with the heat sinks therein, as discussed in more details with reference to FIGS. 5A-5C and FIGS. 6A-6C. The heated coolants may then flow out of the respective cooling blocks to flow to the radiator 380 via a combiner manifold 370. In some instances, one or more of the fluid paths fluidically connecting the cooling blocks to the combiner manifold 370 may have disposed thereon a flow restrictor. For example, the flow restrictors may be selected such that the flow rate of the heated coolants flowing into the radiator from the respective cooling blocks are the same or substantially the same. The heated coolant, once in the radiator 380, may be cooled by cooling fans before returning back to the coolant reservoir 310.

In various embodiments, the cooling parameters of the various modules of an opto-fluidic instrument may be different. For example, a reagent deck may have to be maintained within a first temperature range, where such a first temperature range can be, for instance, a temperature range within which the reagents, or probes therein, remain effective for use in detecting target molecules in a sample. As another example, a SIM may have to be maintained within a second temperature range, such a second temperature range can be, for instance, a temperature range within which target molecules in the sample can be probed effectively by probes. For instance, the reagents deck and/or the SIM may have to be maintained at temperatures below about 10° C., about 5° C., about 3° C., including values and subranges therebetween. On the other hand, the illumination module (e.g., LEDs) and/or the camera module may generate a significant amount of heat, and the cooling parameters of these modules may be to lower their temperatures to a third temperature range and/or a fourth temperature range, respectively, that are suitable for the operation of the modules (e.g., and the opto-fluidic instrument as a whole). For instance, the LEDs and/or the camera module may generate heat that raises their temperatures to as high as about 80° C., which may be reduced to a suitable temperature range (e.g., room temperature) for the proper operation of the modules and the opto-fluidic instrument as a whole.

In such embodiments, the flow rate of the pump pumping the coolant at the coolant reservoir 310 and/or the flow restrictors disposed on the fluid paths connecting the splitting manifold 320 to the cooling blocks, if any, may be selected based on the temperatures of one or more of the modules (e.g., or their respective cooling blocks) and their cooling parameters as noted above. For example, the flow rate of the coolant may be set, and/or the diameter of the flow restrictor orifices may be selected, such that the temperatures of the reagent deck and/or the SIM are maintained within the first and/or second temperature ranges, respectively, while the temperatures of the LEDs and/or the camera module are reduced to within the third and/or fourth temperature ranges, respectively.

In various embodiments, the temperature control of the opto-fluidic instrument, and modules therein, may be dynamic. That is, a system controller (e.g., similar to or same as the system controller 130 of FIG. 1) may receive sensor measurements from sensors coupled to, or disposed at, the modules and may generate and transmit instructions to the pumps based on the received sensor measurements. For example, temperature sensors may be thermally coupled to one or more of SIM 1 cooling block 330a, SIM 2 cooling block 330b, the LED cooling block 340, the camera cooling block 350, reagent deck 1 cooling block 360a, reagent deck 2 cooling block 360b, or any of the fluid paths connecting any of the coolant reservoir 310, the radiator 380, and any of the cooling blocks. Such temperature sensors may measure the temperatures of the cooling block to which the sensors are coupled, or the temperature of coolant flowing in the fluid path to which the sensors are coupled, and transmit the measurements to the system controller. Further, flow rate sensors may also be disposed at said fluid paths, and may measure flow rates of coolant flowing therein. The flow rate sensors may transmit such measurements to the system controller. Examples of a temperature sensor include a thermistor, a thermocouple, a resistive temperature detector, or a semiconductor-based temperature sensor. Examples of a flow rate sensor include a Coriolis flow meter, a differential pressure flow meter, a magnetic flow meter, a multiphase flow meter, an ultrasonic flow meter, or a vortex flow meter. In various embodiments, one or more temperature sensors are positioned at the cool side of each TEC, for example, the TEC of each SIM and the TECs of the reagent deck.

Upon receiving the temperature and/or flow rate measurements, in various embodiments, the system controller may generate instructions based on the received measurements and transmit the same to the pump. In some instances, the instructions may be configured to cause the pump to pump the coolant at such a flow rate that the temperatures of the reagent deck and/or the SIM are maintained within the first and/or second temperature ranges, respectively, and the temperatures of the LEDs and/or the camera module are reduced to within the third and/or fourth temperature ranges, respectively.

For example, a temperature sensor that is thermally coupled to the reagent deck may measure and transmit to the system controller the temperature of the reagent deck and/or the reagent deck cooling block 360 (e.g., which may correspond to the temperature of the reagents in the reagent deck). The first temperature range within which the reagents could be maintained may be bounded by pre-determined minimum and maximum temperatures. In such cases, the system controller may instruct the pump to adjust its flow rate to no greater than a threshold flow rate that corresponds to the pre-determined minimum temperature. That is, upon receiving the instructions, the pump may pump the coolant at a lower flow rate that is less than the threshold flow rate. The lower flow rate of the coolant may result in, after the pumped coolant traverses the reagent deck cooling block, the temperature of the reagents or the reagent deck being equal to or greater than the pre-determined minimum temperature (e.g., because less coolant exchanging heat with the heat sink of the reagent deck cooling block 360 may result in higher temperature for the reagents in the reagent deck).

As another example, a temperature sensor that is thermally coupled to the SIM may measure and transmit to the system controller the temperature of the SIM and/or the SIM cooling block 330 (e.g., which may correspond to the temperature of the sample that is supported by the SIM). The second temperature range within which the sample could be maintained may be bounded by pre-determined minimum and maximum temperatures. In such cases, the system controller may instruct the pump to adjust its flow rate to no greater than a threshold flow rate that corresponds to the pre-determined minimum temperature. That is, upon receiving the instructions, the pump may pump the coolant at a lower flow rate that is less than the threshold flow rate. The lower flow rate of the coolant may result in, after the pumped coolant traverses SIM cooling block, the temperature of the sample or the SIM being equal to or greater than the pre-determined minimum temperature (e.g., because less coolant exchanging heat with the heat sink of the SIM cooling block 330 may result in higher temperature for the sample in the SIM).

In various embodiments, other types of sensors disposed in the opto-fluidic instrument may transmit measurements to the system controller, which may then act based on the received measurements. For example, a liquid level sensor may be coupled to the coolant reservoir 310 and may be configured to measure the level or amount of coolant in the coolant reservoir 310. In such cases, the liquid level sensor may transmit the measurement to the system controller, and the system controller may act based on the measurement. For example, the system controller may output an alert (e.g., to a user interface of the opto-fluidic instrument) indicating the amount of coolant in the coolant reservoir 310. As another example, if for instance the amount of coolant is outside an acceptable volume range, the system controller may prevent the opto-fluidic instrument from operating (e.g., while outputting an alert indicating the issue).

In various embodiments, as discussed above, one or more of the aforementioned cooling blocks (e.g., cooling block(s) 330, LED cooling block 340, camera cooling block 350, reagent deck cooling block 360) may include a heat sink in which heat exchange with coolant may take place. That is, in some instances, the heat sink may be configured to receive coolant from the splitting manifold 320 and release heat to the received coolant while the coolant is circulating therein, before the heated coolant exits the heat sink. FIGS. 5A-5C and FIGS. 6A-6C show schematics of example implementations of heat sinks that include U-shaped fluid paths and fins, respectively, according to various embodiments. With reference to FIG. 5A, a heat sink 510 may be in contact or otherwise thermally coupled to a heat source 505 (e.g., camera module, illumination module including LEDs, etc.), and as such may absorb heat from the heat source 505. In some instances, the heat sink 510 may have therein a U-shaped fluid path 515 therein, wherein a coolant from the coolant reservoir (e.g., or splitting manifold) may flow in via a heat sink inlet, flow therein while absorbing heat from the heat sink 510, and flow out as heated coolant via a heat sink outlet. In various embodiments, where a heat sink 510 has a U shaped fluid path 515, the coolant flows into the heat sink 510 and along a path nearest to the heat source 505 (e.g., at a first distance) and then the resulting heated coolant flows along a path that is at a further distance away from the heat source 505 (e.g., at a second distance that is greater than the first distance) and out of the heat sink 510. In various embodiments, where the heat sink 510 has a straight fluid path, the coolant flows into the heat sink 510 on a first side, along a path near the heat source 505, and then flows out of the heat sink on an opposing side. FIG. 5C shows an example schematic of such a heat sink 550 with a heat sink inlet 540 for allowing coolant 545 flow therein so that the coolant can travel within the heat sink 550 via the U-shaped path absorbing heat from the heat sink 550. The heat sink 550 may also have a heat sink outlet 565 configured to allow the heated coolant 560 flow out of the heat sink 550.

With reference to FIG. 5B, in various embodiments, a module 520 of an opto-fluidic instrument that may have to be maintained within a desired temperature range (e.g., SIM, reagent deck) may be thermally coupled to a thermoelectric cooler (TEC) 525 having a cold side 525a and a hot side 525b. That is, the module 520 may be in contact or otherwise in thermal communication with the cold side 525a of the TEC 525 such that the cold side 525a absorbs heat from the module 520 and transfers the same to the hot side 525b of the module 520. The heat from the hot side 525b is then absorbed by the heat sink 530, which is the same or substantially similar to the heat sink 510 of FIG. 5A. In such cases, the cooling of the heat sink 530 by a coolant flowing in the U-shaped fluid path 535 occurs as described above with reference to FIGS. 5A and 5C. The TEC 525 may maintain the module 520 at a desired temperature.

With reference to FIG. 6A, a heat sink 620 may be in contact or otherwise thermally coupled to a heat source 610 (e.g., camera module, illumination module including LEDs, etc.), and as such may absorb heat from the heat source 610. In some instances, the heat sink 620 may be a finned heat sink. That is, the heat sink 620 may include multiple sheet-metal fins 615 that provide abundant surface area for a coolant traversing therein to absorb heat from the heat sink 620. In some instances, the fins of the heat sink can be skived fins, bonded fins, extruded fins, or stamped fins. In some instances, the heat sink 620 may have an inlet for receiving a coolant 625a from the coolant reservoir (e.g., or splitting manifold). The coolant may traverse the fins 615 while absorbing heat from the heat sink 620, and flow out as heated coolant 625b via a heat sink outlet.

With reference to FIG. 6B, in various embodiments, a module 630 of an opto-fluidic instrument that may have to be maintained within a desired temperature range (e.g., SIM, reagent deck) may be thermally coupled to a thermoelectric cooler (TEC) 640 having a cold side 640a and a hot side 640b. That is, the module 630 may be in contact or otherwise in thermal communication with the cold side 640a of the TEC 640 such that the cold side 640a absorbs heat from the module 630 and transfers the same to the hot side 640b of the module 640. The heat from the hot side 640b is then absorbed by the heat sink 650, which is the same or substantially similar to the heat sink 620 of FIG. 6A. The TEC 640 may maintain the module 630 at a desired temperature.

For example, the heat sink 650 may have an inlet for receiving a coolant 655a from the coolant reservoir (e.g., or splitting manifold). The coolant may traverse the fins 665 while absorbing heat from the heat sink 650, and flow out as heated coolant 655b via a heat sink outlet. FIG. 6C shows an example schematic of such a heat sink 655 with a heat sink inlet 675 for allowing coolant 660 flow therein so that the coolant can traverse 670 the fins of the heat sink 655 absorbing heat from the heat sink 655 to become a heated coolant 680. The heat sink 655 may also have a heat sink outlet 695 that is configured to allow the heated coolant 690 flow out of the heat sink 655.

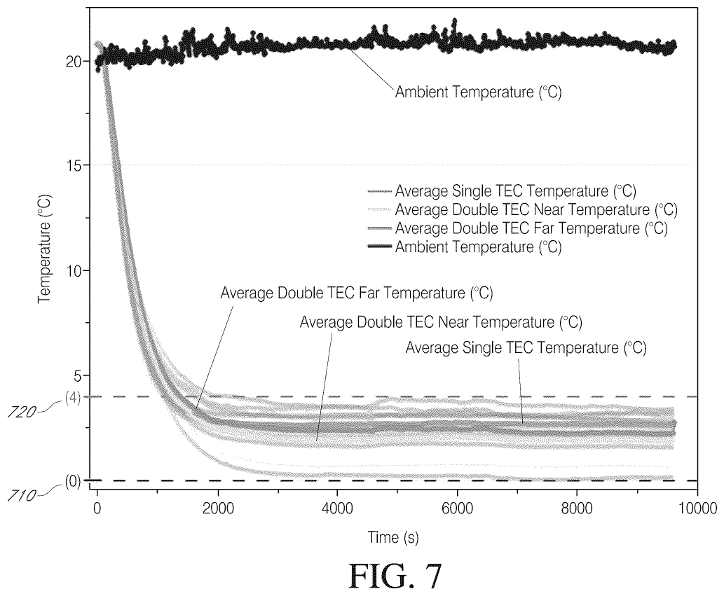

FIG. 7 is a plot illustrating cooling performance of the disclosed heat exchange system in controlling the temperature of reagents in reagent decks of an opto-fluidic instrument, according to various embodiments. In various embodiments, the disclosed heat exchange system was tested on an opto-fluidic instrument that includes two reagent decks. One of the two reagent decks contained a single array of reagent containers and included a reagent deck cooling block that was thermally coupled to a TEC (labeled “Single TEC” in FIG. 7). The other reagent deck contained two arrays of reagent container and included a reagent deck cooling block that was thermally coupled to a pair of TECs (e.g., one TEC in thermal communication with each array) (labeled “Double TEC” in FIG. 7). Both the single TEC and the double TEC were coupled to a temperature sensor.

In various embodiments, the testing of the heat exchange system included activating a pump of a coolant reservoir to pump coolant to the reagent deck cooling module. As shown in FIG. 7, at the start of the test at time t=0s, the ambient environment, the single TEC, and the double TEC were found to have comparable temperature (about 20° C.). Once the testing commenced and the coolant started arriving at the reagent deck cooling block, the temperature of the single TEC, and the temperatures of the double TECs as measured at two ends (“near end” and “far end”) of the double TEC, started dropping sharply. The temperatures of both the single TEC and the double TEC were found to have dipped below the reagent target temperature 720 of about 4° C. within about 15 minutes of the start of the testing, and remained so for the rest of the testing lasting about 3 hrs) while the ambient temperature remained fairly constant at about 21° C.

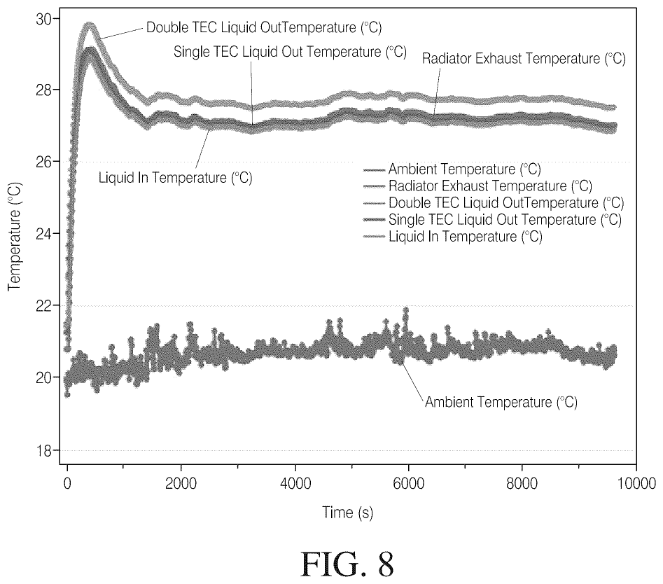

FIG. 8 shows a plot illustrating the temperatures of the coolant during the testing of the heat exchange system discussed with reference to FIG. 7, according to various embodiments. In some instances, a temperature sensor was thermally coupled to a radiator of the opto-fluidic instrument to measure the “radiator exhaust temperature” (e.g., which can be used as a measure of the temperature of the heated coolant being cooled by the cooling fans of the radiator). Further, additional temperature sensors were also thermally coupled to fluid paths flowing coolants out of the cooling block (e.g., that are thermally coupled to the single TEC and double TEC) to measure “single TEC liquid out temperature” and “double TEC liquid out temperature”, respectively. Further, another temperature sensor was thermally coupled to the fluid path directing coolant into the reagent deck cooling block that are thermally coupled to the single TEC and double TEC to measure “liquid in temperature”.

In various embodiments, at the start of the testing at time t=0 s, the coolant has about the same temperature as the ambient environment. Once the testing commenced and the coolant started arriving at the reagent deck cooling block, each one of the “single TEC liquid out temperature”, the “double TEC liquid out temperature”, the “radiator exhaust temperature”, and the “liquid in temperature” sharply increased, indicating that the coolant was heating up by absorbing heat from the reagent deck cooling block, while the ambient temperature remained fairly constant at about 21° C.

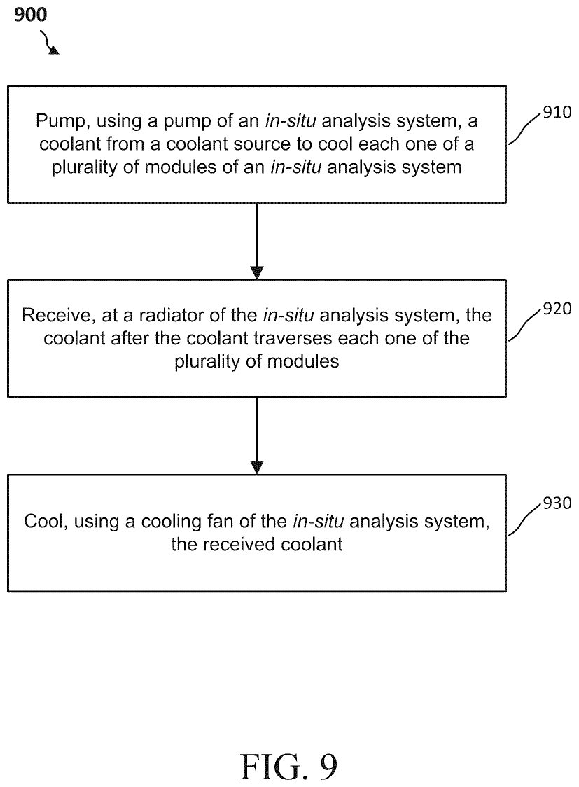

FIG. 9 is a flowchart illustrating a method 900 for controlling the temperature of modules of an opto-fluidic instrument, according to various embodiments. Aspects of the method 900 can be executed by the system controller 130, the fluidics module 140, the ancillary module 170, of FIG. 1, and/or other suitable means for performing the steps. As illustrated, the method 900 includes a number of enumerated steps, but aspects of the method 900 may include additional steps before, after, and in between the enumerated steps. In some embodiments, one or more of the enumerated steps may be omitted or performed in a different order.

At block 910, a pump of an opto-fluidic instrument may pump a coolant from a coolant source to cool each one of a plurality of modules of an opto-fluidic instrument. In various embodiments, the plurality of modules of the opto-fluidic instrument include a sample interface module (SIM), an illumination module, a camera module, and a reagent deck. The SIM is configured to support a sample and includes a SIM cooling block that is thermally coupled to the sample. The illumination module includes a LED cooling block and one or more light emitting diodes (LEDs) that are configured to illuminate the sample. The camera module is configured to image the sample and includes a camera cooling block. The reagent deck is configured to store reagents for treating the sample during a plurality of imaging cycles. Further, the reagent deck includes a reagent deck cooling block that is thermally coupled to the reagents.

At block 920, a radiator of the opto-fluidic instrument may receive the coolant after the coolant traverses each one of the plurality of modules.

At blocks 930, a cooling fan of the opto-fluidic instrument may cool the received coolant. In some instances, the coolant is a liquid coolant. In some instances, the coolant is an air coolant.

Some embodiments of method 900 further comprise measuring, using a temperature sensor thermally coupled to the one of the plurality of modules, a temperature of the one of the plurality of modules. In some instances, the temperature sensor includes a thermistor, a thermocouple, a resistive temperature detector, or a semiconductor-based temperature sensor.

Some embodiments of method 900 further comprise measuring, using a flow rate sensor disposed along a path of the coolant, a flow rate of the coolant flowing via the path. In some instances, the flow rate sensor includes a Coriolis flow meter, a differential pressure flow meter, a magnetic flow meter, a multiphase flow meter, an ultrasonic flow meter, or a vortex flow meter.

Various embodiments of the present disclosure disclose a heat transfer system comprising a reservoir, a radiator, and a pump. In various embodiments, the reservoir is configured to store a liquid coolant. Further, the pump is configured to pump the liquid coolant from the reservoir to the radiator via a plurality of modules of an opto-fluidic instrument. In various instances, the plurality of modules of the opto-fluidic instrument include a sample interface module (SIM), an illumination module, a camera module, and a reagent deck. The SIM is configured to support a sample and includes a SIM cooling block that is thermally coupled to the sample. The illumination module includes a light emitting diode (LED) cooling block and one or more LEDs that are configured to illuminate the sample. The camera module is configured to image the sample and includes a camera cooling block. The reagent deck is configured to store reagents for treating the sample during a plurality of imaging cycles. Further, the reagent deck includes a reagent deck cooling block that is thermally coupled to the reagents.

Various embodiments of the present disclosure disclose a system for controlling temperature of an opto-fluidic instrument. The system for controlling the temperature of the opto-fluidic instrument comprise a reservoir, a radiator, one or more first fluid paths, a pump, a sensor, and a controller. The reservoir is configured to store a liquid coolant. The one or more first fluid paths are configured to connect the reservoir to a plurality of modules of the opto-fluidic instrument. In some instances, the plurality of modules can include the afore-mentioned SIM, illumination module, camera module, and reagent deck. The pump is configured to pump the liquid coolant from the reservoir to at least one of the plurality of modules via the one or more first fluid paths. The sensor is disposed along the one or more first fluid paths or is operationally connected to the one or more of the plurality of modules and is configured to perform a measurement of the one or more first fluid paths or the one or more of the plurality of modules, respectively. The controller is communicatively coupled to the sensor and the pump, and is configured to adjust a flow rate of the pump in response to receiving the measurement from the sensor.

In various embodiments, the systems (e.g., the heat transfer system or the system for controlling temperature of the opto-fluidic instrument) further comprise a liquid level sensor operationally coupled to the reservoir and configured to measure a level of the liquid coolant in the reservoir. In some instances, the systems further comprise a splitting manifold configured to receive the liquid coolant from the reservoir and direct the received liquid coolant to the plurality of modules. In some instances, at least a pair of the plurality of modules are fluidically connected to the splitting manifold in series. In some instances, at least a pair of the plurality of modules are fluidically connected to the splitting manifold in parallel. In some instances, the SIM, the illumination module, the camera module, and the reagent deck are fluidically connected to each other in series. In some instances, the SIM, the illumination module, the camera module, and the reagent deck are fluidically connected to each other in parallel.

In various embodiments, the systems further comprise a first fluid path fluidically connected to the splitting manifold and configured to direct the pumped liquid coolant to at least one of the plurality of modules. In some instances, the systems further comprise a flow regulator positioned on the first fluid path for controlling a flow rate of the liquid coolant flowing therein. In some instances, the flow regulator includes a flow restrictor including a flow restrictor orifice or a flow restrictor valve. In various embodiments, the pump includes at least four pumps configured to individually pump the liquid coolant to the SIM, the illumination module, the camera module, and the reagent deck. In some instances, the pump is configured to pump the liquid coolant at a flow rate no greater than a threshold flow rate of the liquid coolant corresponding to a pre-determined minimum temperature of the sample or the reagents.

In various embodiments, the systems further comprise a temperature sensor thermally coupled to a second fluid path of the liquid coolant fluidically connecting the reservoir to the radiator for measuring a temperature of the liquid coolant flowing therein. In some instances, the second fluid path is configured to transport the liquid coolant from the radiator to the reservoir after the liquid coolant is cooled by the cooling fan. In some instances, the systems further comprise the cooling fan configured to air-cool the liquid coolant flowing via the radiator. In some instances, the systems further comprise a fluid path fluidically connecting the radiator to the reservoir, the fluid path configured to transport the liquid coolant cooled by the cooling fan in the radiator to the reservoir.

In various embodiments, the systems further comprise a temperature sensor thermally coupled to one or more of the plurality of modules of the opto-fluidic instrument for measuring a temperature of the one or more of the plurality of modules. In some instances, the temperature sensor includes a thermistor, a thermocouple, a resistive temperature detector, or a semiconductor-based temperature sensor.

In various embodiments, the systems further comprise a flow rate sensor disposed along a third flow path of the liquid coolant fluidically connecting the reservoir to the radiator. In some instances, the flow rate sensor includes a Coriolis flow meter, a differential pressure flow meter, a magnetic flow meter, a multiphase flow meter, an ultrasonic flow meter, or a vortex flow meter.

In various embodiments, the SIM cooling block, the LED cooling block, or the reagent deck cooling block include a heat sink including fins, an inlet configured to allow the liquid coolant arriving at the SIM, the illumination module, or the reagent deck, respectively, to enter the heat sink to traverse the fins, and an outlet configured to allow the liquid coolant exit the heat sink after traversing the fins. In some instances, the fins of the heat sink are skived fins, bonded fins, extruded fins, or stamped fins. In various embodiments, the SIM cooling block, the LED cooling block, or the reagent deck cooling block include a heat sink with a U-shaped fluid path therein, an inlet at one end of the U-shaped fluid path configured to allow the liquid coolant arriving at the SIM, the illumination module, or the reagent deck, respectively, to enter the heat sink, and an outlet at another end of the U-shaped fluid path configured to allow the liquid coolant exit the heat sink. In some instances, the systems further comprise a thermoelectric cooler (TEC) disposed on the heat sink.

While the present teachings are described in conjunction with various embodiments, it is not intended that the present teachings be limited to such various embodiments. On the contrary, the present teachings encompass various alternatives, modifications, and equivalents, as will be appreciated by those of skill in the art.

In describing the various embodiments, the specification may have presented a method and/or process as a particular sequence of steps. However, to the extent that the method or process does not rely on the particular order of steps set forth herein, the method or process should not be limited to the particular sequence of steps described, and one skilled in the art can readily appreciate that the sequences may be varied and still remain within the spirit and scope of the various embodiments.

### ADDITIONAL RECITED EMBODIMENTS

Embodiment 1: A heat transfer system, comprising: a reservoir configured to store a liquid coolant; a radiator; and a pump configured to pump the liquid coolant from the reservoir to the radiator via a plurality of modules of an opto-fluidic instrument, wherein the plurality of modules include: a sample interface module (SIM) configured to support a sample, the SIM including a SIM cooling block that is thermally coupled to the sample; an illumination module with one or more light emitting diodes (LEDs) configured to illuminate the sample, the illumination module including a LED cooling block; a camera module configured to image the sample, the camera module including a camera cooling block; and a reagent deck configured to store reagents for treating the sample during a plurality of imaging cycles, the reagent deck including a reagent deck cooling block that is thermally coupled to the reagents.

Embodiment 2: The heat transfer system of claim 1, further comprising a liquid level sensor operationally coupled to the reservoir and configured to measure a level of the liquid coolant in the reservoir.

Embodiment 3: The heat transfer system of claim 1 or 2, further comprising a splitting manifold configured to receive the liquid coolant from the reservoir and direct the received liquid coolant to the plurality of modules.

Embodiment 4: The heat transfer system of any of claims 1-3, wherein at least a pair of the plurality of modules are fluidically connected to the splitting manifold in series.

Embodiment 5: The heat transfer system of any of claims 1-3, wherein at least a pair of the plurality of modules are fluidically connected to the splitting manifold in parallel.

Embodiment 6: The heat transfer system of any of the preceding claims, wherein the SIM, the illumination module, the camera module, and the reagent deck are fluidically connected to each other in series.

Embodiment 7: The heat transfer system of any of claims 1-5, wherein the SIM, the illumination module, the camera module, and the reagent deck are fluidically connected to each other in parallel.

Embodiment 8: The heat transfer system of any of claims 3-7, further comprising a first fluid path fluidically connected to the splitting manifold and configured to direct the pumped liquid coolant to at least one of the plurality of modules.

Embodiment 9: The heat transfer system of claim 8, further comprising a flow regulator positioned on the first fluid path for controlling a flow rate of the liquid coolant flowing therein.

Embodiment 10: The heat transfer system of claim 9, wherein the flow regulator includes a flow restrictor including a flow restrictor orifice or a flow restrictor valve.

Embodiment 11: The heat transfer system of any of the preceding claims, wherein the pump includes at least four pumps configured to individually pump the liquid coolant to the SIM, the illumination module, the camera module, and the reagent deck.

Embodiment 12: The heat transfer system of any of the preceding claims, further comprising a temperature sensor thermally coupled to a second fluid path of the liquid coolant fluidically connecting the reservoir to the radiator for measuring a temperature of the liquid coolant flowing therein.

Embodiment 13: The heat transfer system of claim 12, wherein the second fluid path is configured to transport the liquid coolant from the radiator to the reservoir after the liquid coolant is cooled by the cooling fan.

Embodiment 14: The heat transfer system of any of the preceding claims, further comprising a temperature sensor thermally coupled to one or more of the plurality of modules of the opto-fluidic instrument for measuring a temperature of the one or more of the plurality of modules.

Embodiment 15: The heat transfer system of any of claims 10-14, wherein the temperature sensor includes a thermistor, a thermocouple, a resistive temperature detector, or a semiconductor-based temperature sensor.

Embodiment 16: The heat transfer system of any of the preceding claims, further comprising a flow rate sensor disposed along a third flow path of the liquid coolant fluidically connecting the reservoir to the radiator.

Embodiment 17: The heat transfer system of claim 16, wherein the flow rate sensor includes a Coriolis flow meter, a differential pressure flow meter, a magnetic flow meter, a multiphase flow meter, an ultrasonic flow meter, or a vortex flow meter.

Embodiment 18: The heat transfer system of any of the preceding claims, wherein the SIM cooling block, the LED cooling block, or the reagent deck cooling block include a heat sink including fins, an inlet configured to allow the liquid coolant arriving at the SIM, the illumination module, or the reagent deck, respectively, to enter the heat sink to traverse the fins, and an outlet configured to allow the liquid coolant exit the heat sink after traversing the fins.

Embodiment 19: The heat transfer system of claim 18, wherein the fins of the heat sink are skived fins, bonded fins, extruded fins, or stamped fins.

Embodiment 20: The heat transfer system of any of the preceding claims, wherein the SIM cooling block, the LED cooling block, or the reagent deck cooling block include a heat sink with a U-shaped fluid path therein, an inlet at one end of the U-shaped fluid path configured to allow the liquid coolant arriving at the SIM, the illumination module, or the reagent deck, respectively, to enter the heat sink, and an outlet at another end of the U-shaped fluid path configured to allow the liquid coolant exit the heat sink.

Embodiment 21: The heat transfer system of claim 18 or 19, further comprising a thermoelectric cooler (TEC) disposed on the heat sink.

Embodiment 22: The heat transfer system of any of the preceding claims, wherein the pump is configured to pump the liquid coolant at a flow rate no greater than a threshold flow rate of the liquid coolant corresponding to a pre-determined minimum temperature of the sample or the reagents.

Embodiment 23: The heat transfer system of any of the preceding claims, further comprising a cooling fan configured to air-cool the liquid coolant flowing via the radiator.

Embodiment 24: The heat transfer system of claim 23, further comprising a fluid path fluidically connecting the radiator to the reservoir, the fluid path configured to transport the liquid coolant cooled by the cooling fan in the radiator to the reservoir.

Embodiment 25: A system for controlling temperature of an opto-fluidic instrument, comprising: a reservoir configured to store a liquid coolant; a radiator; one or more first fluid paths connecting the reservoir to a plurality of modules of the opto-fluidic instrument, wherein the plurality of modules include: a sample interface module (SIM) configured to support a sample, the SIM including a SIM cooling block that is thermally coupled to the sample; an illumination module with one or more light emitting diodes (LEDs) configured to illuminate the sample, the illumination module including a LED cooling block; a camera module configured to image the sample, the camera module including a camera cooling block; and a reagent deck containing reagents for treating the sample, the reagent deck including a reagent deck cooling block that is thermally coupled to the reagents; a pump configured to pump the liquid coolant from the reservoir to at least one of the plurality of modules via the one or more first fluid paths; a sensor disposed along the one or more first fluid paths or operationally connected to one or more of the plurality of modules, the sensor configured to perform a measurement of the one or more first fluid paths or the one or more of the plurality of modules, respectively; and a controller communicatively coupled to the sensor and the pump, the controller configured to adjust a flow rate of the pump in response to receiving the measurement from the sensor.

Embodiment 26: The system of claim 25, wherein the sensor includes a temperature sensor thermally coupled to the one or more of the plurality of modules and the measurement is a temperature measurement of the one or more of the plurality of modules.

Embodiment 27: The system of claim 26, wherein the temperature sensor includes a thermistor, a thermocouple, a resistive temperature detector, or a semiconductor-based temperature sensor.

Embodiment 28: The system of any of claims 25-27, wherein the sensor includes a flow rate sensor disposed along the one or more first fluid paths and the measurement is a flow rate measurement of the liquid coolant flowing therein.

Embodiment 29: The system of claim 28, wherein the flow rate sensor includes a Coriolis flow meter, a differential pressure flow meter, a magnetic flow meter, a multiphase flow meter, an ultrasonic flow meter, or a vortex flow meter.

Embodiment 30: The system of any of claims 25-29, wherein the one or more first fluid paths fluidically connect the plurality of modules in series.

Embodiment 31: The system of any of claims 25-30, wherein the one or more first fluid paths fluidically connect the plurality of modules in parallel.

Embodiment 32: The system of claim 25, wherein: the sensor includes a temperature sensor thermally coupled to the SIM; the measurement is a temperature measurement of the sample; and the controller is configured to adjust the flow rate of the pump to no greater than a threshold flow rate corresponding to a pre-determined minimum temperature of the sample.

Embodiment 33: The system of claim 25, wherein: the sensor includes a temperature sensor thermally coupled to the reagent deck; the measurement is a temperature measurement of the reagents; and the controller is configured to adjust the flow rate of the pump to no greater than a threshold flow rate corresponding to a pre-determined minimum temperature of the reagents.

Embodiment 34: The system of any of claims 25-33, further comprising a reservoir configured to store the liquid coolant.

Embodiment 35: The system of claim 34, further comprising a radiator and a second fluid path fluidically connecting the radiator to the reservoir, the second fluid path configured to transport the liquid coolant after cooling by the cooling fan in the radiator to the reservoir.

Embodiment 36: A method, comprising: pumping, using a pump of an opto-fluidic instrument, a coolant from a coolant source to cool each one of a plurality of modules of an opto-fluidic instrument, wherein the plurality of modules include: a sample interface module (SIM) configured to support a sample, the SIM including a SIM cooling block that is thermally coupled to the sample; an illumination module with one or more light emitting diodes (LEDs) configured to illuminate the sample, the illumination module including a LED cooling block; a camera module configured to image the sample, the camera module including a camera cooling block; and a reagent deck containing reagents for treating the sample, the reagent deck including a reagent deck cooling block that is thermally coupled to the reagents; receiving, at a radiator of the opto-fluidic instrument, the coolant after the coolant traverses each one of the plurality of modules; and cooling, using a cooling fan of the opto-fluidic instrument, the received coolant.

Embodiment 37: The method of claim 36, further comprising measuring, using a temperature sensor thermally coupled to the one of the plurality of modules, a temperature of the one of the plurality of modules.

Embodiment 38: The method of claim 37, wherein the temperature sensor includes a thermistor, a thermocouple, a resistive temperature detector, or a semiconductor-based temperature sensor.

Embodiment 39: The method of any of claims 36-38, further comprising measuring, using a flow rate sensor disposed along a path of the coolant, a flow rate of the coolant flowing via the path.

Embodiment 40: The method of claim 39, wherein the flow rate sensor includes a Coriolis flow meter, a differential pressure flow meter, a magnetic flow meter, a multiphase flow meter, an ultrasonic flow meter, or a vortex flow meter.

Embodiment 41: The method of any of claims 36-40, wherein the coolant is a liquid coolant.

Embodiment 42: The method of any of claims 36-40, wherein the coolant is an air coolant.

What is claimed is:

1. A heat transfer system, comprising:
a reservoir configured to store a liquid coolant;
a radiator; and
a pump configured to pump the liquid coolant from the reservoir to the radiator via a plurality of modules of an opto-fluidic instrument, wherein the plurality of modules of the include:
a sample interface module (SIM) configured to support a sample, the SIM including a SIM cooling block that is thermally coupled to the sample;
an illumination module with one or more light emitting diodes (LEDs) configured to illuminate the sample, the illumination module including a LED cooling block;
a camera module configured to image the sample, the camera module including a camera cooling block; and
a reagent deck configured to store reagents for treating the sample during a plurality of imaging cycles, the reagent deck including a reagent deck cooling block that is thermally coupled to the reagents.

2. The heat transfer system of claim 1, further comprising a liquid level sensor operationally coupled to the reservoir and configured to measure a level of the liquid coolant in the reservoir.

3. The heat transfer system of claim 1, further comprising a splitting manifold configured to receive the liquid coolant from the reservoir and direct the received liquid coolant to the plurality of modules.

4. The heat transfer system of claim 1, wherein at least a pair of the plurality of modules are fluidically connected to the splitting manifold in series.

5. The heat transfer system of claim 1, wherein at least a pair of the plurality of modules are fluidically connected to the splitting manifold in parallel.

6. The heat transfer system of claim 3, further comprising a first fluid path fluidically connected to the splitting manifold and configured to direct the pumped liquid coolant to at least one of the plurality of modules.

7. The heat transfer system of claim 6, further comprising a flow regulator positioned on the first fluid path for controlling a flow rate of the liquid coolant flowing therein, wherein the flow regulator includes a flow restrictor including a flow restrictor orifice or a flow restrictor valve.

8. The heat transfer system of claim 1, wherein the pump includes at least four pumps configured to individually pump the liquid coolant to the SIM, the illumination module, the camera module, and the reagent deck.

9. The heat transfer system of claim 1, further comprising a temperature sensor thermally coupled to a second fluid path of the liquid coolant fluidically connecting the reservoir to the radiator for measuring a temperature of the liquid coolant flowing therein.

10. The heat transfer system of claim 9, wherein the second fluid path is configured to transport the liquid coolant from the radiator to the reservoir after the liquid coolant is cooled by the cooling fan.

11. The heat transfer system of claim 1, further comprising a temperature sensor thermally coupled to one or more of the plurality of modules of the opto-fluidic instrument for measuring a temperature of the one or more of the plurality of modules.

12. The heat transfer system of claim 9, wherein the temperature sensor includes a thermistor, a thermocouple, a resistive temperature detector, or a semiconductor-based temperature sensor.

13. The heat transfer system of claim 1, further comprising a flow rate sensor disposed along a third flow path of the liquid coolant fluidically connecting the reservoir to the radiator.

14. The heat transfer system of claim 13, wherein the flow rate sensor includes a Coriolis flow meter, a differential pressure flow meter, a magnetic flow meter, a multiphase flow meter, an ultrasonic flow meter, or a vortex flow meter.

15. The heat transfer system of claim 1, wherein the SIM cooling block, the LED cooling block, or the reagent deck cooling block include a heat sink including fins, an inlet configured to allow the liquid coolant arriving at the SIM, the illumination module, or the reagent deck, respectively, to enter the heat sink to traverse the fins, and an outlet configured to allow the liquid coolant exit the heat sink after traversing the fins.

16. The heat transfer system of claim 1, wherein the SIM cooling block, the LED cooling block, or the reagent deck cooling block include a heat sink with a U-shaped fluid path therein, an inlet at one end of the U-shaped fluid path configured to allow the liquid coolant arriving at the SIM, the illumination module, or the reagent deck, respectively, to enter the heat sink, and an outlet at another end of the U-shaped fluid path configured to allow the liquid coolant exit the heat sink.

17. The heat transfer system of claim 1, wherein the pump is configured to pump the liquid coolant at a flow rate no greater than a threshold flow rate of the liquid coolant corresponding to a pre-determined minimum temperature of the sample or the reagents.

18. The heat transfer system of claim 1, further comprising a cooling fan configured to air-cool the liquid coolant flowing via the radiator.

19. A system for controlling temperature of an opto-fluidic instrument, comprising:
a reservoir configured to store a liquid coolant;
a radiator;
one or more first fluid paths connecting the reservoir to a plurality of modules of the opto-fluidic instrument, the plurality of modules including:
a sample interface module (SIM) configured to support a sample, the SIM including a SIM cooling block that is thermally coupled to the sample;
an illumination module with one or more light emitting diodes (LEDs) configured to illuminate the sample, the illumination module including a LED cooling block;
a camera module configured to image the sample, the camera module including a camera cooling block; and
a reagent deck containing reagents for treating the sample, the reagent deck including a reagent deck cooling block that is thermally coupled to the reagents;
a pump configured to pump the liquid coolant from the reservoir to at least one of the plurality of modules via the one or more first fluid paths;
a sensor disposed along the one or more first fluid paths or operationally connected to one or more of the plurality of modules, the sensor configured to perform a measurement of the one or more first fluid paths or the one or more of the plurality of modules, respectively; and
a controller communicatively coupled to the sensor and the pump, the controller configured to adjust a flow rate of the pump in response to receiving the measurement from the sensor.

20. A method, comprising:
pumping, using a pump of an opto-fluidic instrument, a coolant from a coolant source to cool each one of a plurality of modules of an opto-fluidic instrument, the plurality of modules including:
a sample interface module (SIM) configured to support a sample, the SIM including a SIM cooling block that is thermally coupled to the sample;
an illumination module with one or more light emitting diodes (LEDs) configured to illuminate the sample, the illumination module including a LED cooling block;
a camera module configured to image the sample, the camera module including a camera cooling block; and
a reagent deck containing reagents for treating the sample, the reagent deck including a reagent deck cooling block that is thermally coupled to the reagents;
receiving, at a radiator of the opto-fluidic instrument, the coolant after the coolant traverses each one of the plurality of modules; and
cooling, using a cooling fan of the opto-fluidic instrument, the received coolant.
